(19) United States
(12) Patent Application Publication
(10) Pub. No.: US 2026/0255856 A1
(43) Pub. Date: Aug. 27, 2026

(54) LIGHT EMITTING DEVICE AND ELECTRONIC APPARATUS

(71) Applicant: SONY SEMICONDUCTOR SOLUTIONS CORPORATION, KANAGAWA (JP)

(72) Inventor: YOSHINORI UCHIDA, KANAGAWA (JP)

(21) Appl. No.: 19/163,036

(22) PCT Filed: Mar. 27, 2024
(86) PCT No.: PCT/JP2024/012157

§ 371 Date: Sep. 8, 2025

(30) Foreign Application Priority Data
Mar. 29, 2023 (JP) 2023-054346

(51) Int. Cl. H10K 59/80

(52) U.S. Cl. CPC H10K 59/879

(57) ABSTRACT

Provided is a light emitting device including a plurality of light emitting elements arranged on a substrate, in which each of the plurality of light emitting elements includes a first electrode provided on the substrate, a light emitting layer that is stacked on the first electrode and emits light, a second electrode that is stacked on the light emitting layer and transmits the light from the light emitting layer, and a plurality of rod-shaped lenses provided above the second electrode, and the plurality of rod-shaped lenses is provided apart from each other.

### FIELD

The present disclosure relates to a light emitting device and an electronic apparatus.

### BACKGROUND

In recent years, a display device (light emitting device) using an organic electroluminescence (EL) element as a light emitting element has been developed. The display device includes, for example, a plurality of pixels (light emitting elements) configured by a lower electrode, a light emitting layer stacked on the lower electrode, and an upper electrode stacked on the light emitting layer. By a predetermined voltage supplied to the lower electrode and the upper electrode, the light emitting layer sandwiched between the lower electrode and the upper electrode emits light. For example, as an example of such a display device, a display device in Patent Literature described below can be exemplified.

### CITATION LIST

### Patent Literature

Patent Literature 1: WO 2020/162355 A

### SUMMARY

### Technical Problem

In a case where the display device (light emitting device) is applied to, for example, a display device for augmented reality (AR) or the like, it is required to make a display brighter in order to improve visibility. Then, for this purpose, the light from the pixels (light emitting elements) is required to be extracted to a front upper side of the pixels and efficiently incident on a set optical system (for example, a light guide plate or the like) located above the pixels as parallel light.

However, in conventional display devices (light emitting devices), there is a limit to efficiently extracting light from the pixels as parallel light to the upper front side. Therefore, the present disclosure proposes a light emitting device and an electronic apparatus capable of efficiently extracting light from a pixel as parallel light to an upper front side of the pixel.

### Solution to Problem

According to the present disclosure, there is provided a light emitting device including a plurality of light emitting elements arranged on a substrate. In the light emitting device, each of the plurality of light emitting elements includes: a first electrode provided on the substrate; a light emitting layer that is stacked on the first electrode and emits light; a second electrode that is stacked on the light emitting layer and transmits the light from the light emitting layer; and a plurality of rod-shaped lenses provided above the second electrode, and the plurality of rod-shaped lenses is provided apart from each other.

Furthermore, according to the present disclosure, there is provided an electronic apparatus equipped with a light emitting device including a plurality of light emitting elements arranged on a substrate. In the light emitting device, each of the plurality of light emitting elements includes: a first electrode provided on the substrate; a light emitting layer that is stacked on the first electrode and emits light; a second electrode that is stacked on the light emitting layer and transmits the light from the light emitting layer; and a plurality of rod-shaped lenses provided above the second electrode, and the plurality of rod-shaped lenses is provided apart from each other.

### BRIEF DESCRIPTION OF DRAWINGS

FIG. 1 is a schematic diagram illustrating an example of an overall configuration of a light emitting device according to an embodiment of the present disclosure.

FIG. 2 is a schematic circuit diagram for describing a connection relationship in a subpixel of an m-th row and an n-th column.

FIG. 3 is a sectional view for describing an example of a configuration of a subpixel according to a comparative example.

FIG. 4 is a sectional view and a plan view for describing an example of a configuration of a subpixel according to a first embodiment of the present disclosure.

FIG. 5 is an enlarged view of a region A illustrated in FIG. 4.

FIG. 6 is an explanatory diagram for describing the subpixel according to the first embodiment of the present disclosure.

FIG. 7A is a sectional view (part 1) for describing an example of a configuration of a subpixel according to a second embodiment of the present disclosure.

FIG. 7B is a sectional view (part 2) for describing an example of the configuration of the subpixel according to the second embodiment of the present disclosure.

FIG. 8 is a sectional view for describing an example of a configuration of a subpixel according to Modification 1 of the second embodiment of the present disclosure.

FIG. 9 is a sectional view for describing an example of a configuration of a subpixel according to Modification 2 of the second embodiment of the present disclosure.

FIG. 10 is a sectional view for describing an example of a configuration of a main part of a subpixel according to a third embodiment of the present disclosure.

FIG. 11A is a sectional view (part 1) for describing an example of a configuration of a main part of a subpixel according to Modification 1 of the third embodiment of the present disclosure.

FIG. 11B is a sectional view (part 2) for describing an example of the configuration of the main part of the subpixel according to Modification 1 of the third embodiment of the present disclosure.

FIG. 12A is a plan view (part 1) for describing an example of a configuration of a main part of a subpixel according to Modification 2 of the third embodiment of the present disclosure.

FIG. 12B is a plan view (part 2) for describing an example of a configuration of a main part of a subpixel according to Modification 2 of the third embodiment of the present disclosure.

FIG. 13 is a plan view for describing an example of a configuration of a subpixel according to Modification 3 of the third embodiment of the present disclosure.

FIG. 14 is a sectional view for describing an example of a configuration of a subpixel according to a fourth embodiment of the present disclosure.

FIG. 15A is an explanatory diagram (part 1) for describing a method of manufacturing a subpixel according to a fifth embodiment of the present disclosure.

FIG. 15B is an explanatory diagram (part 2) for describing the method of manufacturing the subpixel according to the fifth embodiment of the present disclosure.

FIG. 16A is an explanatory diagram (part 1) for describing another method of manufacturing the subpixel according to the fifth embodiment of the present disclosure.

FIG. 16B is an explanatory diagram (part 2) for describing another method of manufacturing the subpixel according to the fifth embodiment of the present disclosure.

FIG. 17A is a sectional view (part 1) for describing an example of a configuration of a subpixel according to a sixth embodiment of the present disclosure.

FIG. 17B is a sectional view (part 2) for describing an example of the configuration of the subpixel according to the sixth embodiment of the present disclosure.

FIG. 18A is a sectional view (part 1) for describing an example of a configuration of a subpixel according to Modification 1 of the sixth embodiment of the present disclosure.

FIG. 18B is a sectional view (part 2) for describing an example of the configuration of the subpixel according to Modification 1 of the sixth embodiment of the present disclosure.

FIG. 19A is a sectional view (part 1) for describing an example of a configuration of a subpixel according to Modification 2 of the sixth embodiment of the present disclosure.

FIG. 19B is a sectional view (part 2) for describing an example of a configuration of a subpixel according to Modification 2 of the sixth embodiment of the present disclosure.

FIG. 20 is a schematic sectional view for describing a first example of a resonator structure.

FIG. 21 is a schematic sectional view for describing a second example of the resonator structure.

FIG. 22 is a schematic sectional view for describing a third example of the resonator structure.

FIG. 23 is a schematic sectional view for describing a fourth example of the resonator structure.

FIG. 24 is a schematic sectional view for describing a fifth example of the resonator structure.

FIG. 25 is a schematic sectional view for describing a sixth example of the resonator structure.

FIG. 26 is a schematic sectional view for describing a seventh example of the resonator structure.

FIG. 27A is a front view illustrating an example of an external appearance of a digital still camera.

FIG. 27B is a rear view illustrating an example of the external appearance of the digital still camera.

FIG. 28 is an external view of a head mounted display.

FIG. 29 is an external view of a see-through head mounted display.

FIG. 30 is an external view of a television apparatus.

FIG. 31 is an external view of a smartphone.

FIG. 32A is a diagram (part 1) illustrating an internal configuration of an automobile.

FIG. 32B is a diagram (part 2) illustrating an internal configuration of the automobile.

### DESCRIPTION OF EMBODIMENTS

Hereinafter, preferred embodiments of the present disclosure will be described in detail with reference to the accompanying drawings. Note that, in the present specification and the drawings, constituent elements having substantially the same functional configuration are denoted by the same reference signs to omit redundant description. In the present specification and the drawings, some of a plurality of constituent elements having substantially the same or similar functional configuration are distinguished by attaching different alphabets after the same reference signs. However, in a case where it is not necessary to distinguish each of the plurality of constituent elements having substantially the same or similar functional configuration, only the same reference sign is attached.

The drawings referred to in the following description are drawings for promoting the description of an embodiment of the present disclosure and the understanding of the description, and shapes, dimensions, ratios, and the like illustrated in the drawings may be different from actual ones for the sake of clarity. Furthermore, a display device (light emitting device) illustrated in the drawings can be appropriately modified in design in consideration of the following description and known techniques.

The description of specific lengths and shapes in the following description does not mean only the same values as mathematically defined numerical values or geometrically defined shapes. Specifically, the description of the specific lengths and shapes in the following description includes a case where there is an allowable difference (error or distortion) in a light emitting element, a light emitting device, manufacturing steps, and use and operation of the above and a shape similar to the shape.

In the following description of circuits (electrical connections), unless otherwise specified, “electrically connected” means that a plurality of elements are connected such that electricity (signals) conducts. In addition, “electrically connected” in the following description includes not only that a plurality of elements are directly and electrically connected but also that a plurality of elements are connected indirectly via other elements and electrically.

Note that the description will be given in the following order.
1. Overall configuration of light emitting device according to embodiment of present disclosure
2. Background of achievement to creation of embodiments of present disclosure
3. First embodiment
4. Second embodiment
5. Third embodiment
6. Fourth embodiment
7. Fifth Embodiment
8. Sixth Embodiment
9. Summary
10. Modification
11. Application examples
12. Supplement

### 1. Overall Configuration of Light Emitting Device According to Embodiment of Present Disclosure

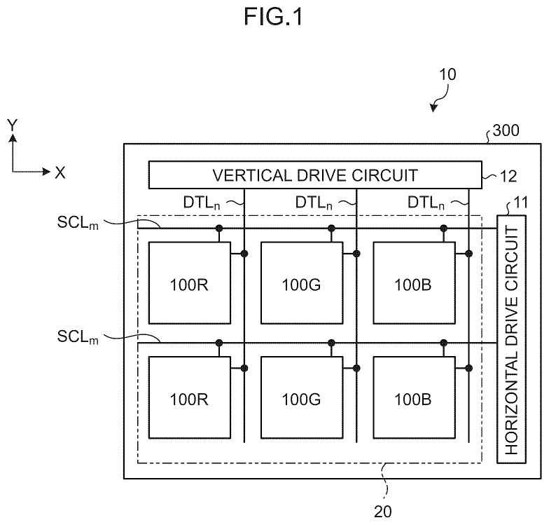

An example of an overall configuration of an organic electro luminescence (EL) light emitting device 10 (hereinafter, simply referred to as “light emitting device 10”) according to an embodiment of the present disclosure used as a display device or a lighting device will be described with reference to FIG. 1. FIG. 1 is a schematic diagram illustrating an example of the overall configuration of the light emitting device 10 according to the embodiment of the present disclosure.

The light emitting device 10 is, for example, a device in which light emitting elements such as an organic light emitting diode (OLED) or a micro-OLED are formed in an array. Such a light emitting device 10 can be applied to, for example, a display device for virtual reality (VR), mixed reality (MR), or augmented reality (AR), an electronic view finder (EVF), a small projector, or the like as a display device. The light emitting device 10 can also be applied to various lighting devices.

The light emitting device 10 includes a display region provided on a substrate 300 and a peripheral region provided on a peripheral edge of the display region. As illustrated in FIG. 1, in the display region of the light emitting device 10, for example, a plurality of subpixels (light emitting elements) 100R, 100G, and 100B are arranged in a matrix. The subpixel 100R can emit red light, the subpixel 100G may emit green light, and the subpixel 100B may emit blue light. Note that, in the following description, the subpixels 100R, 100G, and 100B are referred to as subpixels 100 unless otherwise distinguished.

Furthermore, in the present embodiment, one pixel (pixel) 20 is configured by, for example, combining three types of subpixels 100R, 100G, and 100B that emit different types of light. Note that, in the present embodiment, the number and arrangement of each of the three types of subpixels 100R, 100G, and 100B included in one pixel 20 are not limited. In the present embodiment, one pixel 20 is not required to be configured by the plurality of subpixels 100 that emit different lights as described above, and may be configured by the plurality of subpixels 100 that emit the same color light. The pixel 20 means a minimum unit (pixel) controlled at the time of light emission control of the light emitting device 10, and includes the plurality of subpixels 100 treated as one unit at the time of the control. That is, in the present embodiment, the light emitting device 10 includes the plurality of pixels 20 arranged in a matrix on the substrate 300.

As illustrated in FIG. 1, a horizontal drive circuit 11 and a vertical drive circuit 12 are provided in the peripheral region of the light emitting device 10.

The horizontal drive circuit 11 can scan each subpixel 100 in units of rows (in FIG. 1, a direction extending along an X direction is referred to as a row direction) when a signal to each subpixel 100 is written, and sequentially supply a scanning signal to each scanning line SCLₘ. The horizontal drive circuit 11 can include, for example, a shift register or the like that sequentially shifts (transfers) a start pulse in synchronization with an input clock pulse.

The vertical drive circuit 12 can supply a signal voltage of a signal corresponding to luminance information supplied from a signal supply source (not illustrated) to the subpixels 100 selected in units of columns (in FIG. 1, a direction extending along a Y direction is referred to as a column direction) via a signal line DTLₙ.

In the embodiment of the present disclosure, the configuration of the light emitting device 10 is not limited to the configuration illustrated in FIG. 1. Although not illustrated, a setting optical system may be provided from, for example, a light guide plate or the like above the display region, for example. That is, the configuration illustrated in FIG. 1 is merely an example, and the light emitting device 10 according to the embodiment of the present disclosure can have various configurations.

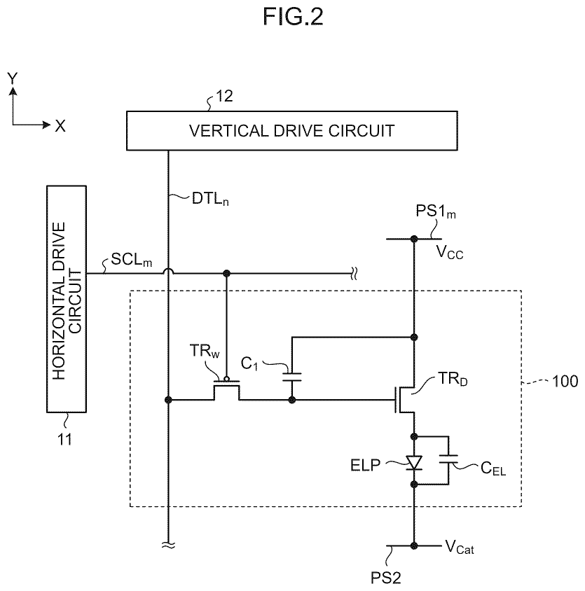

Next, a circuit configuration of the subpixel 100 in an m-th row and an n-th column will be described with reference to FIG. 2. FIG. 2 is a schematic circuit diagram for describing a connection relationship in the subpixel 100 in the m-th row and the n-th column.

In the light emitting device 10, as described above, the subpixels 100 including a light emitting elements ELP are arranged in a two-dimensional matrix while being connected to the scanning line SCLₘ extending in the row direction (X direction in FIG. 1) and the signal line DTLₙ extending in the column direction (Y direction in FIG. 1).

Furthermore, as illustrated in FIG. 2, the light emitting device 10 includes a feed line PS1ₘ that supplies a drive voltage to the subpixel 100, and a common feed line PS2 that is commonly connected to all the subpixels 100. Then, a predetermined drive voltage V_{cc} or the like is supplied from a power supply unit (not illustrated) to the feed line PS1ₘ, and a common voltage V_{cat} (for example, ground potential) is supplied to the common feed line PS2.

Here, the number of scanning lines SCL and the number of feed lines PS1 are each M. The subpixels 100 in the m-th row (where m=1, 2 . . . , P) are connected to the m-th scanning line SCLₘ and the moth feed line PS1ₘ, and constitute one display element row. Note that FIG. 2 illustrates only the scanning line SCLₘ and the feed line PS1ₘ. Here, the number of signal lines DTL is N. The subpixel 100 in the n-th column (where n=1, 2 . . . , N) is connected to the n-th signal line DILₙ. Note that FIG. 2 illustrates only the signal line DTLₙ. Hereinafter, the subpixel 100 located in the m-th row and the n-th column may be referred to as (n, m)-th subpixel 100.

Then, as described above, the light emitting device 10 is sequentially scanned row by row by the scanning signal from the horizontal drive circuit 11. Specifically, in the light emitting device 10, the M subpixels 100 arranged in the m-th row are simultaneously driven. In other words, in the M subpixels 100 arranged along the row direction, a light emission and non-light emission timing is controlled in units of rows to which the subpixels belong. For example, in a case where a display frame rate of the light emitting device 10 is FR (times/second), a scanning period per row (so-called horizontal scanning period) when the light emitting device 10 is sequentially scanned row by row is less than (1/FR)×(1/P) seconds.

As illustrated in FIG. 2, the subpixel 100 includes the light emitting element ELP and a drive circuit that drives the light emitting element ELP. The light emitting element ELP includes an organic electroluminescence light emitting element. The drive circuit includes a write transistor TR_{W}, a drive transistor TR_{D}, and a capacity portion C₁. When a current flows through the light emitting element ELP via the drive transistor TR_{D}, the light emitting element ELP can emit light. Each transistor includes, for example, a p-channel field effect transistor.

As illustrated in FIG. 2, in the subpixel 100, one source/drain region of the drive transistor TR_{D} is electrically connected to one end of the capacity portion C₁ and the feed line PS1ₘ, and the other source/drain region is electrically connected to one end (specifically, an anode electrode) of the light emitting element ELP. A gate electrode of the drive transistor TR_{D} is connected to the other source/drain region of the write transistor TR_{W}, and is electrically connected to the other end of the capacity portion C₁.

As illustrated in FIG. 2, one source/drain region of the write transistor TR_{w} is electrically connected to the signal line DTLₙ, and the gate electrode of the write transistor TR_{w} is electrically connected to the scanning line SCLₘ.

As illustrated in FIG. 2, the other end (specifically, a cathode electrode) of the light emitting element ELP is electrically connected to the common feed line PS2. Furthermore, a predetermined cathode voltage V_{cat} is supplied to the common feed line PS2. Note that in FIG. 2, the capacitance of the light emitting element ELP is represented by a reference sign C_{EL}.

An outline of driving of the subpixel 100 will be described. In the subpixel 100, when the write transistor TR_{w} is brought into a conductive state by the scanning signal from the horizontal drive circuit 11 in a state where a voltage corresponding to the luminance of an image to be displayed is supplied from the vertical drive circuit 12 to the signal line DTLₙ, the voltage corresponding to the luminance is written in the capacity portion C₁. After the write transistor TR_{w} is brought into a non-conductive state, a current flows through the drive transistor TR_{D} in accordance with the voltage held in the capacity portion C₁, and thus, the light emitting element ELP emits light.

Note that, in the embodiment of the present disclosure, the configuration of the drive circuit that controls the light emission of the light emitting element ELP is not limited to the configuration illustrated in FIG. 2. Therefore, the configuration illustrated in FIG. 2 is merely an example, and the light emitting device 10 according to the embodiment of the present disclosure can have various configurations.

### 2. Background of Achievement to Creation of Embodiments of Present Disclosure

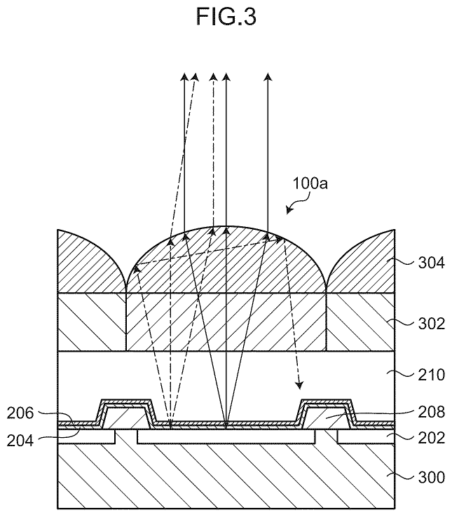

Next, before describing the embodiment of the present disclosure, a background in which the present inventors have created the embodiment of the present disclosure will be described with reference to FIG. 3. FIG. 3 is a sectional view for describing an example of a configuration of a subpixel 100a according to a comparative example. Here, the comparative example means the subpixel 100a which the present inventors have studied before making the embodiment of the present disclosure.

In the comparative example, as illustrated in FIG. 3, each subpixel 100a includes an anode electrode (first electrode) 202 provided on a substrate 300, a light emitting layer 204 stacked on the anode electrode 202, and a cathode electrode (second electrode) 206 that is stacked on the light emitting layer 204 and transmits light from the light emitting layer 204. Furthermore, in the comparative example, on the substrate 300, an insulating film 208 that partitions the subpixel 100a is provided between the adjacent anode electrodes 202.

Then, as illustrated in FIG. 3, the subpixel 100a is covered with a protective film 210, and a color filter 302 and an on-chip lens 304 are provided on the protective film 210 for each subpixel 100a.

In the subpixel 100a according to such a comparative example, a predetermined voltage is supplied to the anode electrode 202 and the cathode electrode 206, and then, the light emitting layer 204 sandwiched between the anode electrode 202 and the cathode electrode 206 emits light. Specifically, in the comparative example, light is emitted from the light emitting layer 204 along a direction from the anode electrode 202 toward the cathode electrode 206. In other words, the subpixel 100a according to the comparative example is a light emitting element of a top emission type.

In consideration of application of the light emitting device 10 to a display device for AR or the like, in order to improve visibility of the light emitting device 10, the display is required to be brighter. Then, for this purpose, the light from the subpixel 100a is required to be efficiently incident on a set optical system (for example, a light guide plate or the like) (not illustrated) located above the subpixel 100a as parallel light.

In the set optical system such as the light guide plate, an angle of light that can be captured is limited. For example, the set optical system can capture only light within a range of ± several degrees or less with respect to a perpendicular line extending in a front direction. However, since the subpixel 100a is a surface light emitting element in which the light emitting layer 204 emits light and the emission light has Lambertian distribution spreading in an emission direction, the set optical system can capture only part of the emission light from the subpixel 100a. That is, by using the subpixel 100a according to the comparative example, it is difficult to cause all the light to be efficiently incident on the set optical system, and thus there is a limit to making the light emitting device 10 brighter.

In such a situation, in order to make the light emitting device 10 brighter, the on-chip lens 304 is provided, for example, for each subpixel 100a in the comparative example in order to collimate (parallelize) the emitted light from the subpixel 100a and cause the emitted light to be incident on the set optical system. However, in the on-chip lens 304, the light can be collimated to some extent for a point light source with Lambertian distribution, but there is a limit to collimating all light with a surface light source such as the subpixel 100a. Specifically, as indicated by an arrow in FIG. 3, part of the light from the light emitting layer 204 (indicated by the solid line arrow at the center in the drawing) is collimated by the on-chip lens 304 and emitted to the outside, but another part of the light from the light emitting layer 204 (indicated by the broken line arrow on the left in the drawing) is not collimated by the on-chip lens 304 and may be reflected to the inside in some cases. Therefore, in the comparative example, even by using the on-chip lens 304, the parallel light cannot be efficiently extracted to a front upper side of the subpixel 100a, and thus, the set optical system can capture only part of the emitted light from the subpixel 100a. In the following description, the front surface of the subpixels 100 and 100a refers to a surface of the cathode electrode 206 in a stacked body of the anode electrode 202, the light emitting layer 204, and the cathode electrode 206 when the subpixels 100 and 100a are viewed from above the substrate 300.

Therefore, the present inventors have intensively studied in such a situation, and conceived a configuration of providing a plurality of rod-shaped lenses above one subpixel 100. In the embodiment of the present disclosure created by the present inventors, since the light from the subpixel 100 can be collimated by using the plurality of rod-shaped lenses, more parallel light can be efficiently extracted to the front upper side of the subpixel 100 and efficiently incident on the set optical system than with the on-chip lens 304. Therefore, in the present embodiment, since the light from the subpixel 100 can be efficiently incident on the set optical system, the light emitting device 10 becomes brighter and the visibility is improved. Furthermore, in the present embodiment, since the light from the subpixel 100 can be efficiently incident on the set optical system, power consumption of the light emitting device 10 can be further reduced. Hereinafter, details of the embodiment of the present disclosure created by the present inventors will be sequentially described.

### 3. First Embodiment

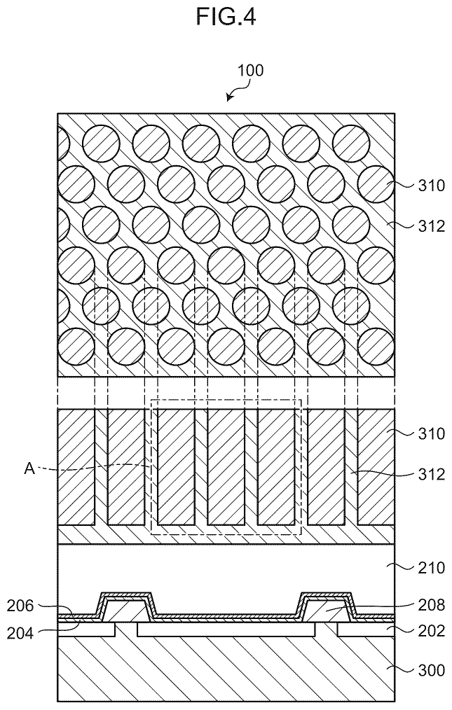

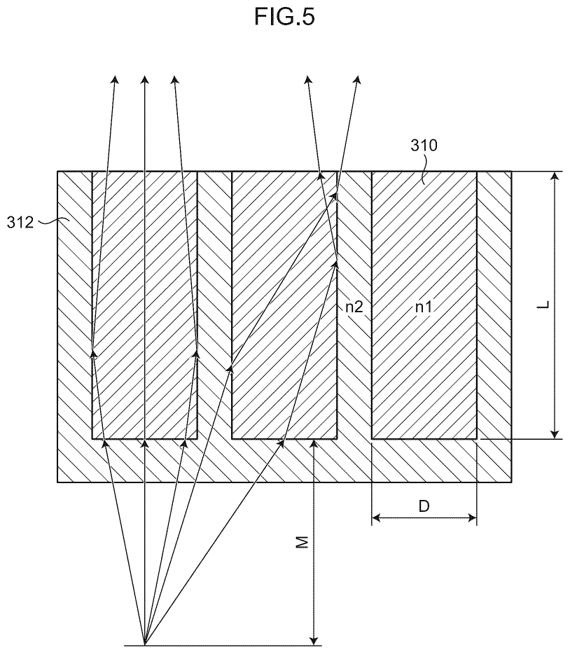

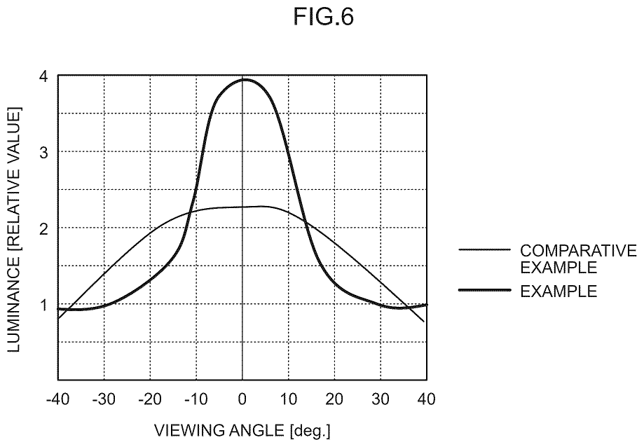

First, a first embodiment of the present disclosure created by the present inventors will be described with reference to FIGS. 4 to 6. FIG. 4 is a sectional view and a plan view for describing an example of a configuration of the subpixel 100 according to the present embodiment. Specifically, the upper part of FIG. 4 illustrates a plan view of the subpixel 100, and the lower part of FIG. 4 illustrates a sectional view of the subpixel 100 cut in a direction perpendicular to the plane of the substrate 300. FIG. 5 is an enlarged view of a region A illustrated in the lower part of FIG. 4. Furthermore, FIG. 6 is an explanatory diagram for describing the subpixel 100 according to the present embodiment, and specifically illustrates distribution of luminance with respect to a viewing angle in the present embodiment (Example) and a comparative example.

In the present embodiment, as in the comparative example, the pixel 20 is configured by combining, for example, three types of subpixels 100R, 100G, and 100B (in FIG. 4, indicated by reference numeral 100) that emit light of different colors. Here, the subpixel 100R can emit red light (for example, visible light having a wavelength of about 640 nm to 770 nm) , the subpixel 100G can emit green light (for example, visible light having a wavelength of about 490 nm to 550 nm), and the subpixel 100B can emit blue light (for example, visible light having a wavelength of about 430 nm to 490 nm). Note that, in the present embodiment, the number and arrangement of each of the three types of subpixels 100R, 100G, and 100B included in one pixel 20 are not limited. Furthermore, in the present embodiment, the pixel 20 may include a subpixel 100 that emits light such as white light other than red light, blue light, and green light. In addition, in the present embodiment, each subpixel 100 included in the pixel 20 may emit the same color light.

In the present embodiment, as illustrated in FIG. 4, as in the comparative example, the subpixel 100 includes the anode electrode (first electrode) 202 provided on the substrate 300, the light emitting layer 204 that is stacked on the anode electrode 202 and emits light, and the cathode electrode (second electrode) 206 that is stacked on the light emitting layer 204 and transmits light from the light emitting layer 204.

Specifically, the substrate 300 can be constituted by a glass substrate such as high strain point glass, soda glass, borosilicate glass, forsterite, lead glass, or quartz glass, a semiconductor substrate such as amorphous silicon or polycrystalline silicon, a resin substrate such as polymethyl methacrylate, polyvinyl alcohol, polyvinyl phenol, polyether sulfone, polyimide, polycarbonate, polyethylene terephthalate, or polyethylene naphthalate, or the like.

The anode electrode 202 of a light emitting element 200 may also have a function as a reflection layer, and preferably include a metal film having as high a reflectance as possible and a large work function in order to enhance light extraction efficiency. Examples of such a metal film include a metal film containing at least one of a simple substance or an alloy of metal elements such as chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), or silver (Ag). Specific examples of the alloy include an aluminum (Al) alloy such as an AlNi alloy or an AlCu alloy, and a silver (Ag) alloy such as an MgAg alloy. Furthermore, the anode electrode 202 may be formed by a transparent conductive film such as indium tin oxide (ITO), indium zinc oxide (IZO), or zinc oxide (ZnO).

Furthermore, in the present embodiment, too, as in the comparative example, the insulating film 208 that partitions the subpixel 100 is provided between the adjacent anode electrodes 202 on the substrate 300. Note that, in the present embodiment, the anode electrode 202 may be electrically connected to the anode electrode 202 of the adjacent subpixel 100.

The light emitting layer 204 provided on the anode electrode 202 includes an organic material or an inorganic material, and is, for example, a layer capable of emitting white light. The light emitting layer 204 may include a hole injection layer (not illustrated) and a hole transport layer (not illustrated) provided adjacent to the anode electrode 202, and an electron transport layer (not illustrated) provided adjacent to the cathode electrode 206. In other words, the light emitting layer 204 can have a structure in which the hole injection layer, the hole transport layer, the light emitting layer 204, and the electron transport layer (not illustrated) are stacked from the side of the anode electrode 202. Note that the hole injection layer functions as a layer for enhancing efficiency of hole injection into the light emitting layer 204, and also functions as a buffer layer for suppressing leakage. The hole transport layer functions as a layer that enhances efficiency of hole transport to the light emitting layer 204. In the light emitting layer 204, generation of an electric field causes recombination of electrons and holes, and can generate light. The electron transport layer functions as a layer that enhances efficiency of electron transport to the light emitting layer 204. Furthermore, the light emitting layer 204 may have an electron injection layer (not illustrated) between the electron transport layer and the cathode electrode 206. The electron injection layer functions as a layer that enhances the efficiency of electron injection.

Note that, in the present embodiment, the configuration of the light emitting layer 204 is not limited to the above configuration, and layers other than the hole injection layer and the light emitting layer 204 can be provided as necessary. Furthermore, in the present embodiment, the light emitting layer 204 may be configured to emit light of a color other than white light, such as red light, blue light, and green light, for example. In the present embodiment, the light emitting layers 204 of the light emitting elements 200 of all the subpixels 100 may have the same structure or may have different structures, and the structure is not limited.

Furthermore, the light emitting layer 204 is continuously provided on the anode electrodes 202 of the subpixels 100 adjacent to each other, in other words, the light emitting layer 204 is provided as one common layer for each subpixel 100. Note that, in the present embodiment, the configuration of the light emitting layer 204 is not limited to the above configuration, and the light emitting layer 204 may be divided from the light emitting layer 204 of the adjacent subpixel 100.

The cathode electrode 206 provided on the light emitting layer 204 is a transparent electrode having transparency for light generated in the light emitting layer 204, and in the following description, the transparent electrode also includes a semi-transparent electrode. The cathode electrode 206 can be formed by, for example, a metal film containing at least one of a simple substance or an alloy of a metal element such as aluminum (Al), magnesium (Mg), calcium (Ca), sodium (Na), or silver (Ag). Specific examples of the alloy include an aluminum (Al) alloy such as an MgAg alloy or an AlLi alloy, and a silver (Ag) alloy. Furthermore, the cathode electrode 206 may be formed by a transparent conductive film such as indium tin oxide (ITO), indium zinc oxide (IZO), or zinc oxide (ZnO).

The cathode electrode 206 is continuously provided on the light emitting layer 204 of the subpixels 100 adjacent to each other, in other words, the cathode electrode 206 is provided as one common layer for each subpixel 100. Note that, in the present embodiment, the configuration of the cathode electrode 206 is not limited to the above configuration, and the cathode electrode 206 may be divided from the cathode electrode 206 of the adjacent subpixel 100.

Furthermore, in the present embodiment, the protective film 210 that transmits light from the light emitting layer 204 is stacked on the cathode electrode 206. Specifically, the protective film 210 is continuously provided on the cathode electrodes 206 of the subpixels 100 adjacent to each other, in other words, the protective film 210 is provided as one common layer for each subpixel 100.

The protective film 210 can be formed by an oxide film such as silicon oxide (SiO₂), aluminum oxide (Al₂O₃), or titanium oxide (TiO₂), a nitride film such as silicon nitride (SiN), a resin material such as silicon oxynitride (SiON), an acrylic resin, or an epoxy resin, or the like.

Furthermore, in the present embodiment, as illustrated in FIG. 4, a plurality of rod-shaped lenses 310 is provided for one subpixel 100, and the plurality of rod-shaped lenses 310 are arranged apart from each other. For example, the rod-shaped lens 310 is provided on the protective film 210 and has a cylindrical shape having a long axis extending along a stacking direction of the subpixel 100, and has a diameter having a length equal to or longer than a wavelength of light emitted by the subpixels 100. Note that, in the present embodiment, the diameter of the rod-shaped lens 310 preferably has a length equal to or longer than the wavelength of the light emitted by the subpixel 100. However, since a certain effect can be obtained even if the diameter is equal to or shorter than the wavelength of the light, in the present embodiment, the diameter of the rod-shaped lens 310 is not limited to a length equal to or longer than the wavelength of the light emitted by the subpixel 100. The rod-shaped lens 310 is surrounded by a peripheral portion (peripheral region) 312, and the peripheral portion 312 has a refractive index lower than the rod-shaped lens 310.

In the present embodiment, as illustrated in FIG. 5 which is an enlarged view of the region A in FIG. 4, light from the light emitting layer 204 enters the rod-shaped lens 310, travels inside the rod-shaped lens 310, is reflected at an interface between the rod-shaped lens 310 and the peripheral portion 312, and is guided as parallel light to the front upper side of the subpixel 100. That is, the rod-shaped lens 310 functions like a waveguide that guides the parallel light along the stacking direction of the subpixels 100. In the present embodiment, as illustrated in FIG. 5, light traveling straight from the light emitting layer 204 along the stacking direction of the subpixels 100 can be guided to the front upper side of the subpixel 100 by the rod-shaped lens 310 immediately above. Furthermore, in the present embodiment, as illustrated in FIG. 5, light traveling straight from the light emitting layer 204 at an angle with respect to the stacking direction of the subpixels 100 can be guided to the front upper side of the subpixel 100 by another rod-shaped lens 310. Therefore, in the present embodiment, light from any position on the surface of the light emitting layer 204 and light having an angle with respect to the stacking direction of the subpixels 100 can be extracted as parallel light to the front upper side of the subpixel 100.

Furthermore, in the present embodiment, a diameter D and a height L of the rod-shaped lens 310, a distance M from the light emitting layer 204 to the rod-shaped lens 310, and the like are determined in accordance with the relationship between a refractive index n1 of the rod-shaped lens 310 and a refractive index n2 of the peripheral portion 312, the wavelength of light from the light emitting layer 204, and the like such that light is suitably extracted to the front surface by the rod-shaped lens 310. Note that, since the wavelength of the light from the light emitting layer 204 has a certain width, the determination is preferably made in consideration of such a width of the wavelength.

Furthermore, in the present embodiment, by accurately forming the rod-shaped lens 310 in a desired shape, extraction of light to the front surface by the rod-shaped lens 310 is controlled. In the present embodiment, it is possible to accurately form the rod-shaped lens 310 having a desired shape by forming a trench or embedding the rod-shaped lens in the trench by a semiconductor manufacturing technique. The rod-shaped lens 310 can be easily aligned by formation by a semiconductor manufacturing technique. Furthermore, in the present embodiment, by providing the plurality of rod-shaped lenses 310 apart from each other, the rod-shaped lens 310 and the peripheral portion 312 can be easily formed separately, and the interface that reflects light can be easily formed in a desired form.

For example, three or more rod-shaped lenses 310 are preferably provided on one subpixel 100. Specifically, three or more rod-shaped lenses 310 are preferably provided in a width direction of one subpixel 100. Furthermore, the rod-shaped lenses 310 are preferably provided at equal positions in the subpixel 100 in order to guide the light from the light emitting layer 204 to the front upper side of the subpixel 100.

Specifically, the rod-shaped lens 310 is formed by a material having a high refractive index. For example, the rod-shaped lens 310 is preferably formed by a material having the refractive index n1 of about 1.6 to 2.1 at room temperature. Specifically, the rod-shaped lens 310 can be formed by at least one material selected from the group consisting of an oxide film such as titanium oxide (TiO₂), a nitride film such as silicon nitride (SiN), silicon oxynitride (SiON), and a resin material such as an epoxy resin.

In the present embodiment, the peripheral portion 312 is formed by a material having a low refractive index lower than the refractive index of the rod-shaped lens 310. For example, the peripheral portion 312 is preferably formed by a material having the refractive index n2 of about 1.0 to 1.7 at room temperature. Specifically, the peripheral portion 312 can be formed by, for example, at least one material selected from the group consisting of an oxide film such as silicon oxide (SiO₂) or aluminum oxide (Al₂O₃), and a resin material such as an acrylic resin or an epoxy resin. In the present embodiment, the difference in refractive index between the rod-shaped lens 310 and the peripheral portion 312 is preferably 0.2 or more, and more preferably 0.4 or more. In the present embodiment, by setting the difference in refractive index in this manner, light is refracted at the interface between the rod-shaped lens 310 and the peripheral portion 312, and parallel light can be efficiently extracted to the front upper side of the subpixel 100.

Furthermore, in the present embodiment, since the rod-shaped lenses 310 are separated from each other, the peripheral portion 312 may be filled with air (air gap) (refractive index 1.0).

As described above, in the present embodiment, by providing the plurality of rod-shaped lenses 310 on one subpixel 100, the light of the light emitting layer 204 can be efficiently extracted as parallel light to the front upper side of the subpixel 100. As a result, in the present embodiment, light can be efficiently incident on the set optical system, and the light emitting device 10 can be brighter and the visibility can be improved. Furthermore, in the present embodiment, since the light from the subpixel 100 can be efficiently incident on the set optical system, power consumption of the light emitting device 10 can be further reduced.

Note that the present embodiment is not limited to the configuration illustrated in FIG. 4, and for example, as described later, the color filter 302 may be stacked, and the configuration can be appropriately changed in accordance with desired characteristics and the like.

FIG. 6 illustrates distribution of luminance with respect to the viewing angle in the present embodiment (Example) and the comparative example. As illustrated in FIG. 6, in the present embodiment (example) in which the plurality of rod-shaped lenses 310 is provided above one subpixel 100, it can be seen that light is efficiently extracted to the front upper side (near the viewing angle of 0 degrees) of the subpixel 100 as compared with the comparative example using the on-chip lens 304. That is, the set optical system such as the light guide plate can capture only the light having the angle in the range of ± several degrees or less with respect to the perpendicular line extending in the front direction. However, in the present embodiment, as compared with the comparative example, most of the light from the subpixel 100 can be extracted as light having an angle in a range of ± several degrees or less. Therefore, the light can be efficiently incident on the set optical system.

### 4. Second Embodiment

### 4.1 Embodiment

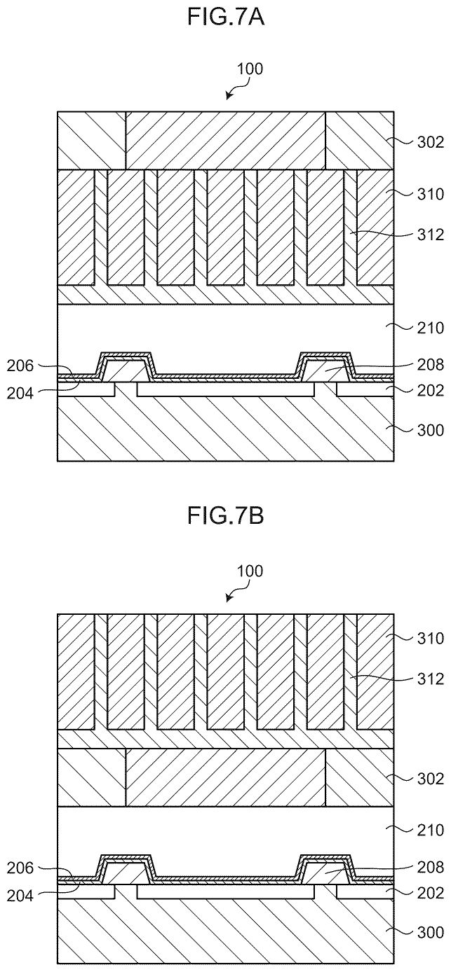

Next, a second embodiment of the present disclosure will be described with reference to FIGS. 7A and 7B. FIGS. 7A and 7B are sectional views for describing an example of the configuration of the subpixel 100 according to the present embodiment, and correspond to the drawing illustrated in the lower part of FIG. 4 described above. Specifically, FIGS. 7A and 7B are sectional views of the subpixel 100 taken along a direction perpendicular to the plane of the substrate 300.

In the present embodiment, as in the comparative example, the color filter 302 may be provided for each subpixel 100. Specifically, as illustrated in FIG. 7A, in the present embodiment, the color filter 302 is stacked above the plurality of rod-shaped lenses 310. Furthermore, the color filter 302 is provided so as to correspond to each subpixel 100.

Alternatively, as illustrated in FIG. 7B, in the present embodiment, the color filter 302 is stacked below the plurality of rod-shaped lenses 310. Furthermore, the color filter 302 is provided so as to correspond to each subpixel 100.

The color filter 302 can be formed by a color filter that transmits a red wavelength component, a color filter that transmits a green wavelength component, or a color filter that transmits a blue wavelength component. For example, the color filter 302 can be formed of a material having a refractive index of about 1.6 to 1.7, and specifically, for example, can be formed by a material in which a pigment or a dye is dispersed in a transparent binder such as an acrylic resin.

### 4.2 Modification 1

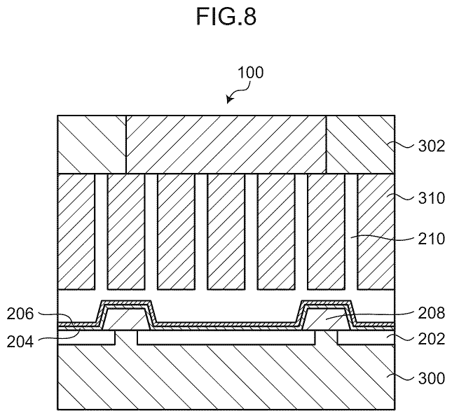

Next, Modification 1 of the second embodiment of the present disclosure will be described with reference to FIG. 8. FIG. 8 is a sectional view for describing an example of the configuration of the subpixel 100 according to Modification 1, and corresponds to the drawing illustrated in the lower part of FIG. 4 described above. Specifically, FIG. 8 is a sectional view of the subpixel 100 taken along a direction perpendicular to the plane of the substrate 300.

In the present embodiment, the position of the rod-shaped lens 310 is not limited as long as the rod-shaped lens 310 is provided above the light emitting layer 204. For example, as illustrated in FIG. 8, the rod-shaped lens 310 may be provided in the protective film 210. In Modification 1, since the rod-shaped lens 310 can be disposed closer to the light emitting layer 204, it is possible to avoid color mixing caused by light incident from the adjacent subpixel 100.

In this modification, the protective film 210 is formed by a material having a low refractive index lower than the refractive index of the rod-shaped lens 310, similarly to the peripheral portion 312. For example, the protective film 210 is preferably formed by a material having the refractive index n2 of about 1.4 to 1.6 at room temperature. Specifically, the protective film 210 can be formed by, for example, at least one material selected from the group consisting of an oxide film such as silicon oxide (SiO₂) or aluminum oxide (Al₂O₃), and a resin material such as an acrylic resin or an epoxy resin.

### 4.3 Modification 2

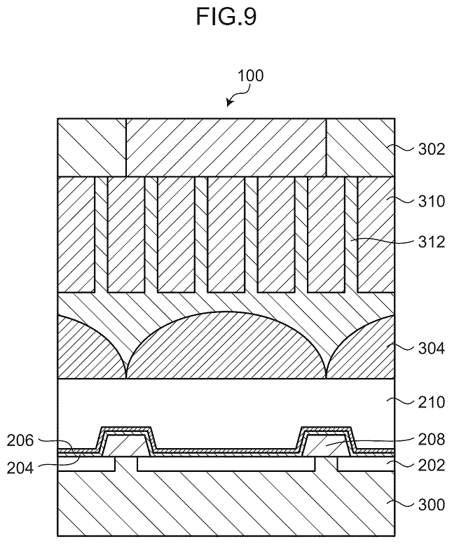

Next, Modification 2 of the second embodiment of the present disclosure will be described with reference to FIG. 9. FIG. 9 is a sectional view for describing an example of the configuration of the subpixel 100 according to Modification 2, and corresponds to the drawing illustrated in the lower part of FIG. 4 described above. Specifically, FIG. 9 is a sectional view of the subpixel 100 taken along a direction perpendicular to the plane of the substrate 300.

In Modification 2, the on-chip lens 304 is stacked below the rod-shaped lens 310. In Modification 2, since the light from the light emitting layer 204 is condensed by the on-chip lens 304 and is then incident on the rod-shaped lens 310, a collimating effect by the rod-shaped lens 310 can be further enhanced. Furthermore, in Modification 2, since the light is condensed by the on-chip lens 304, it is possible to prevent the light from the adjacent subpixel 100 from entering and causing color mixing.

Specifically, the on-chip lens 304 can be formed by, for example, a styrene resin, an acrylic resin, a styrene-acrylic copolymer resin, a siloxane resin, or the like.

Note that the present embodiment and modification are not limited to the configurations illustrated in FIGS. 7A, 7B, 8, and 9, and can be appropriately changed in accordance with desired characteristics and the like.

### 5. Third Embodiment

### 5.1 Embodiment

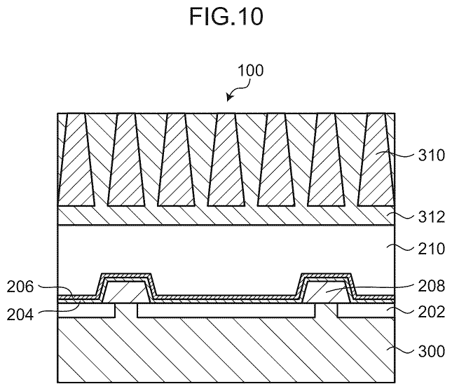

Next, a third embodiment of the present disclosure will be described with reference to FIG. 10. FIG. 10 is a sectional view for describing an example of the configuration of the subpixel 100 according to the present embodiment, and corresponds to the drawing illustrated in the lower part of FIG. 4 described above. Specifically, FIG. 10 is a sectional view of the subpixel 100 taken along a direction perpendicular to the plane of the substrate 300.

In the present embodiment, the shape of the rod-shaped lens 310 is not limited. For example, as illustrated in FIG. 10, the rod-shaped lens 310 has a tapered shape expanding downward in the stacking direction. In other words, the diameter of an upper surface of the rod-shaped lens 310 is smaller than the diameter of a lower surface. In the present embodiment, since the rod-shaped lens 310 having such a shape can further prevent light from the light emitting layer 204 from spreading, the efficiency of extracting parallel light to the front upper side of the subpixel 100 by the rod-shaped lens 310 can be further enhanced.

### 5.2 Modification 1

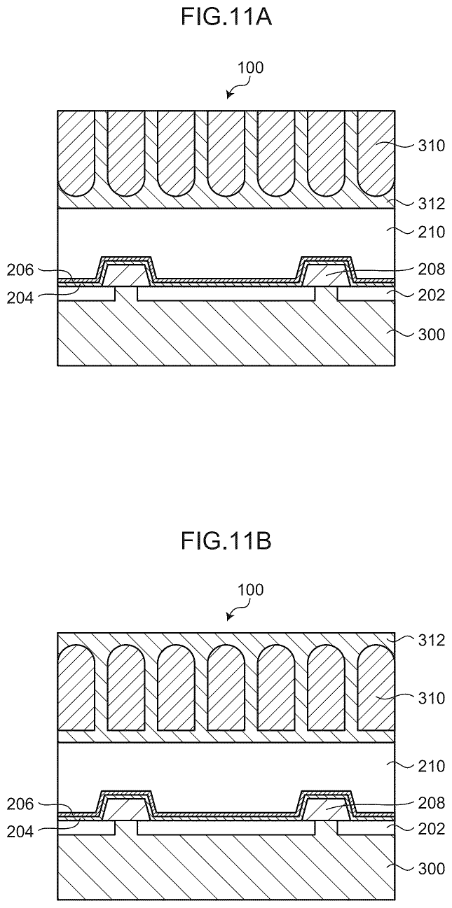

Next, Modification 1 of the third embodiment of the present disclosure will be described with reference to FIGS. 11A and 11B. FIGS. 11A and 11B are sectional views for describing an example of the configuration of the subpixel 100 according to Modification 1, and correspond to the drawing illustrated in the lower part of FIG. 4 described above, and specifically, are sectional views when the subpixel 100 is cut in a direction perpendicular to the plane of the substrate 300.

In Modification 1, the rod-shaped lens 310 has a shape of a condenser lens (condenser lens shape) on the upper surface (upper end) or the lower surface (lower end). In the first modification, by providing such a shape, not only the light is guided but also the light is effectively condensed, so that the efficiency of the extraction of the parallel light to the front upper side of the subpixel 100 by the rod-shaped lens 310 can be further enhanced.

Specifically, in FIG. 11A, the rod-shaped lens 310 has the shape of a condenser lens on the lower surface. In FIG. 11B, the rod-shaped lens 310 has the shape of a condenser lens on the upper surface.

### 5.3 Modification 2

Next, Modification 2 of the third embodiment of the present disclosure will be described with reference to FIGS. 12A and 12B. FIGS. 12A and 12B are plan views for describing the configuration of a main part of the subpixel 100 according to Modification 2, and specifically, are plan views of the rod-shaped lenses 310 as viewed from above, and correspond to the drawing illustrated in the upper part of FIG. 4.

For example, as illustrated in FIG. 12A, the rod-shaped lenses 310 may have a polygonal shape, a circular shape, or an elliptical shape in plan view. For example, as illustrated in FIG. 12B, the rod-shaped lenses 310 may have different diameters D in plan view. In this modification, the shape and size of the rod-shaped lens 310 are preferably determined such that the parallel light is suitably extracted to the front upper side by the rod-shaped lens 310.

In this modification, the diameter D of the rod-shaped lens 310 is preferably determined in accordance with the wavelength of light emitted from the corresponding subpixel 100. Furthermore, in this modification, the length or the shape of the diameter D of the rod-shaped lens 310 may be determined in accordance with the position of the subpixel 100 in the display region of the light emitting device 10.

### 5.4 Modification 3

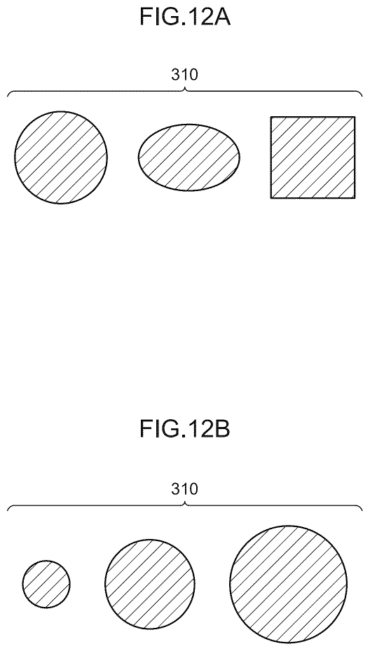

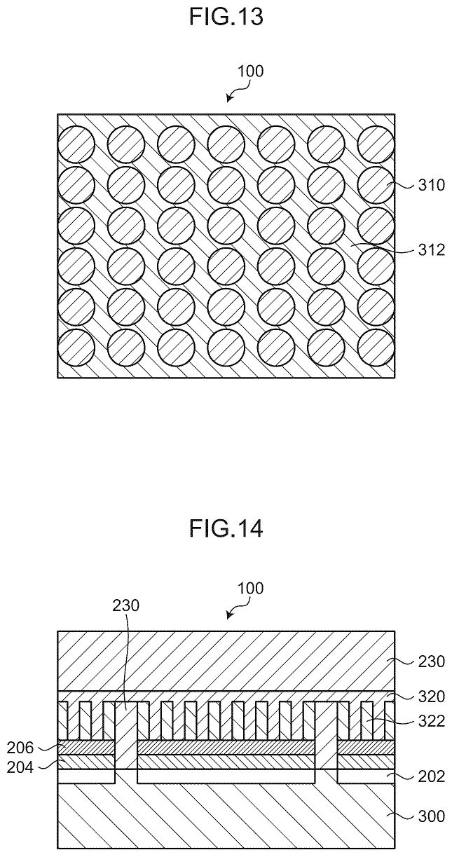

Next, Modification 3 of the third embodiment of the present disclosure will be described with reference to FIG. 13. FIG. 13 is a plan view for describing the configuration of the subpixel 100 according to Modification 3, and specifically, corresponds to the drawing illustrated in the upper part of FIG. 4 described above.

In the first embodiment illustrated in the upper part of FIG. 4, the plurality of rod-shaped lenses 310 are arranged in a close-packed manner, but the embodiment of the present disclosure is not limited to this arrangement. As illustrated in FIG. 13, the plurality of rod-shaped lenses 310 may be arranged along the left-right direction and the up-down direction in the drawing. In the embodiment described so far, the plurality of rod-shaped lenses 310 has been arranged symmetrically in the subpixel 100, but in this modification, the present disclosure is not limited to this arrangement. For example, the plurality of rod-shaped lenses 310 may be asymmetric in accordance with the position of the subpixel 100 in the display region of the light emitting device 10. For example, the plurality of rod-shaped lenses 310 may be arranged so as to be symmetric with each other in the subpixel 100 located in a central portion of the display region of the light emitting device 10, and the plurality of rod-shaped lenses 310 may be arranged so as to be asymmetric with each other in the subpixel 100 located in a peripheral portion of the display region of the light emitting device 10. In this manner, light may be efficiently collected in a predetermined direction.

Note that the present embodiment and modification are not limited to the configurations illustrated in FIGS. 10, 11A, 11B, 12A, 12B, and 13, and can be changed in accordance with desired characteristics and the like.

### 6. Fourth Embodiment

In the embodiment of the present disclosure described so far, the cathode electrode 206 is continuously provided on the light emitting layer 204 of the subpixels 100 adjacent to each other, in other words, the cathode electrode 206 is provided as one common layer for each subpixel 100. However, in the present embodiment, the configuration of the cathode electrode 206 is not limited to the above configuration. Therefore, a fourth embodiment of the present disclosure having a configuration in which the cathode electrode 206 is divided will be described below.

Next, a fourth embodiment of the present disclosure will be described with reference to FIG. 14. FIG. 14 is a sectional view for describing an example of the configuration of the subpixel 100 according to the present embodiment, and correspond to the drawing illustrated in the lower part of FIG. 4 described above, and specifically, is a sectional view when the subpixel 100 is cut in a direction perpendicular to the plane of the substrate 300.

In the present embodiment, as illustrated in FIG. 14, the light emitting layer 204 provided on the anode electrode 202 is divided for each subpixel 100. In the present embodiment, the cathode electrode 206 provided on the light emitting layer 204 is also divided for each subpixel 100.

In the present embodiment, as illustrated in FIG. 14, a plurality of contacts 320 is provided on the cathode electrode 206. The contact 320 serves a function of electrically connecting the divided cathode electrodes 206 to each other. In the present embodiment, the contact 320 can have a similar function to the rod-shaped lens 310 in the embodiment of the present disclosure described above, for example, by being formed by a transparent conductive material having a high refractive index and having a refractive index of around 2.0. Specifically, the contact 320 is formed by a transparent conductive film such as indium tin oxide (ITO), indium zinc oxide (IZO), or zinc oxide (ZnO), for example. In the present embodiment, each of the plurality of contacts 320 is formed as, for example, a cylinder separated from each other, similarly to the rod-shaped lens 310 described above, and each contact 320 is connected to each other above the contact.

In the present embodiment, too, a peripheral portion 322 surrounding the contact 320 is formed by a material having a low refractive index lower than the refractive index of the contact 320. For example, the peripheral portion 322 is preferably formed by a material having the refractive index n2 of about 1.7 to 1.8 at room temperature. Specifically, the peripheral portion 322 can be formed by, for example, silicon nitride (SiN) or the like.

Note that the present embodiment is not limited to the configuration illustrated in FIG. 14, and can be appropriately changed in accordance with desired characteristics and the like.

### 7. Fifth Embodiment

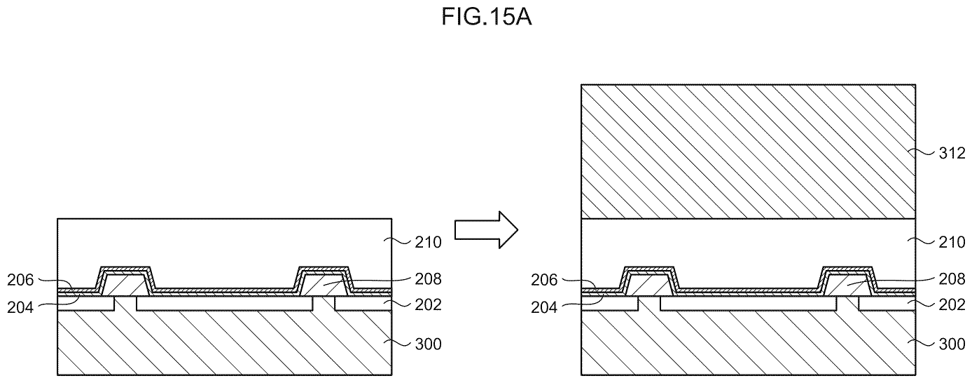

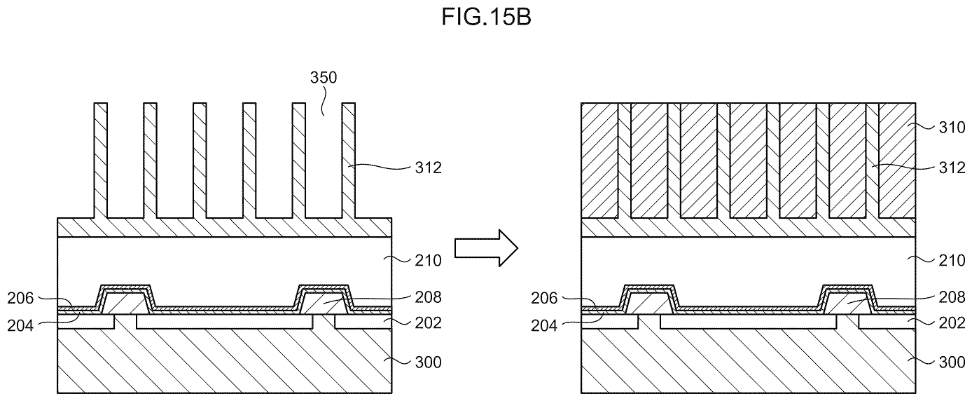

Next, an example of a method of manufacturing the subpixel 100 according to the present embodiment will be described with reference to FIGS. 15A and 15B. FIGS. 15A and 15B are explanatory diagrams for describing the method of manufacturing the subpixel 100 according to the present embodiment, and correspond to the sectional view in the lower part of FIG. 4.

First, as illustrated on the left side in FIG. 15A, a patterned anode electrode 202 is formed on the substrate 300, and the light emitting layer 204 and the cathode electrode 206 are sequentially stacked on the anode electrode 202. Furthermore, the protective film 210 is stacked by a chemical vapor deposition (CVD) method, an atomic layer deposition (ALD) method, or the like. Next, as illustrated on the right side in FIG. 15A, the peripheral portion 312 is formed on the protective film 210. When the peripheral portion 312 includes an inorganic material such as silicon oxide, a film can be formed by, for example, the CVD method, and when the peripheral portion includes an acrylic resin material, a film can be formed by applying, for example, spin coating or the like.

Furthermore, as illustrated on the left side in FIG. 15B, a mask having a predetermined pattern is formed on the peripheral portion 312 by using photolithography, etching is performed in accordance with the pattern of the mask, and a trench 350 is formed in the peripheral portion 312. At this time, an etching stopper layer may be provided at a position to be a bottom surface of the trench 350. Furthermore, as illustrated on the right side in FIG. 15B, the rod-shaped lens 310 is formed in the trench 350. The rod-shaped lens 310 may be provided so as to protrude from the trench 350, or the upper surface may be planarized by etching, chemical mechanical polishing (CMP), or the like.

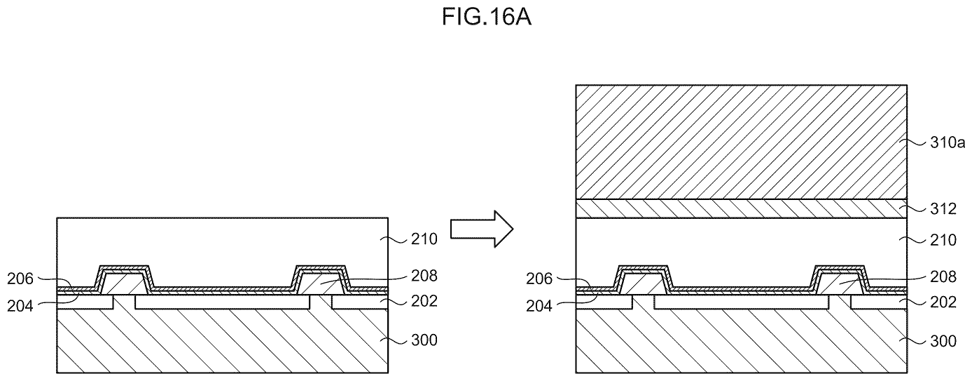

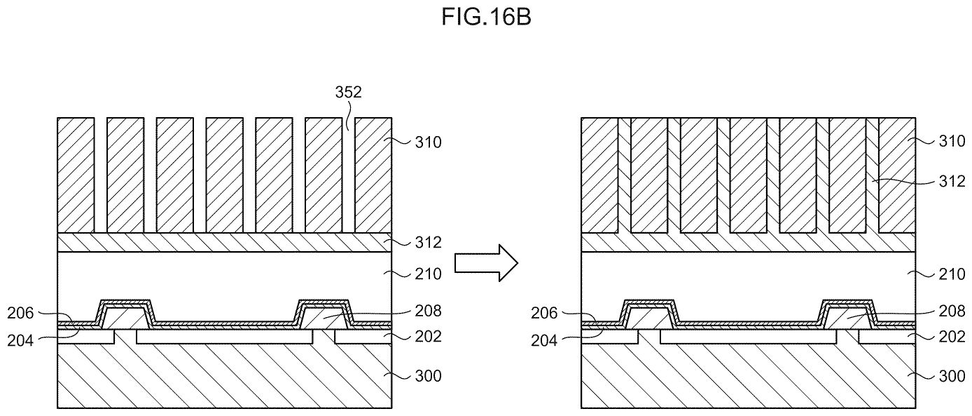

Furthermore, other manufacturing methods can be applied. Next, another method of manufacturing the subpixel 100 according to the present embodiment will be described with reference to FIGS. 16A and 16B. FIGS. 16A and 16B are explanatory diagrams for describing the method of manufacturing the subpixel 100 according to the present embodiment, and correspond to the sectional view in the lower part of FIG. 4.

First, as illustrated on the left side in FIG. 16A, the patterned anode electrode 202 is formed on the substrate 300, and the light emitting layer 204 and the cathode electrode 206 are sequentially stacked on the anode electrode 202. Furthermore, the protective film 210 is stacked by the CVD method, the ALD method, or the like. Next, as illustrated on the right side in FIG. 16A, the peripheral portion 312 is formed on the protective film 210, and a lens material 310a is formed on the peripheral portion 312.

Furthermore, as illustrated on the left side in FIG. 16B, a mask having a predetermined pattern is formed on the lens material 310a by using photolithography, etching is performed in accordance with the pattern of the mask, and the rod-shaped lens 310 is formed. Furthermore, as illustrated on the right side in FIG. 16B, the peripheral portion 312 is formed so as to embed a trench 352 between the rod-shaped lenses 310. At this time, a film may be formed under a condition of poor embeddability in the trench 352 to close only the upper surface of the trench 352 and leave a cavity in the trench 352.

Note that the manufacturing method described here is an example, and can be appropriately changed in the present embodiment.

That is, the subpixel 100 according to an embodiment of the present disclosure can be manufactured by using a method, a device, and conditions used for manufacturing a general semiconductor device. Each subpixel 100 according to the present embodiment can be manufactured by an existing method of manufacturing a semiconductor device.

Examples of the above method include a physical vapor deposition (PVD) method, the CVD method, and the ALD method. Examples of the PVD method include a vacuum vapor deposition method, an electron beam (EB) vapor deposition method, various sputtering methods (magnetron sputtering method, a radio frequency (RF)-direct current (DC) coupled bias sputtering method, an electron cyclotron resonance (ECR) sputtering method, a counter target sputtering method, a high frequency sputtering method, and the like), an ion plating method, a laser ablation method, a molecular beam epitaxy (MBE) method, and a laser transfer method. Examples of the CVD method include a plasma CVD method, a thermal CVD method, an organic metal (MO) CVD method, and a photo CVD method. Furthermore, other methods include an electrolytic plating method, an electroless plating method, a spin coating method, an immersion method, a cast method, a micro-contact printing method, a drop cast method, various printing methods such as a screen printing method, an inkjet printing method, an offset printing method, a gravure printing method, and a flexographic printing method, a stamping method, a spray method, and various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calendar coater method. Furthermore, examples of a patterning method include chemical etching such as shadow mask, laser transfer, and photolithography, and physical etching using ultraviolet rays, laser, and the like. In addition, examples of a planarization technique include a CMP method, a laser planarization method, and a reflow method.

In the present embodiment, as described above it is possible to accurately form the rod-shaped lens 310 having a desired shape by forming the trench or embedding the rod-shaped lens in the trench by the semiconductor manufacturing technique. Therefore, in the present embodiment, the rod-shaped lens 310, which can be formed by the semiconductor manufacturing technique, is easy to align, and a manufacturing cost of the light emitting device 10 is not significantly increased.

### 8. Sixth Embodiment

### 8.1 Embodiment

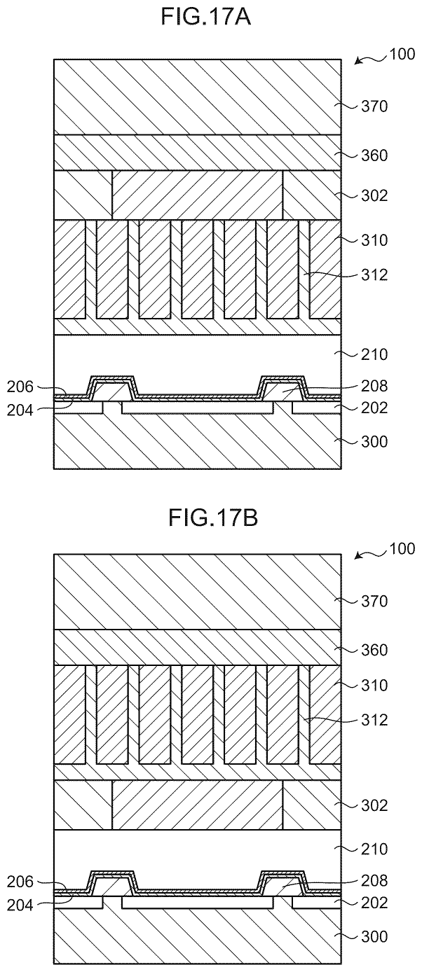

Next, a sixth embodiment of the present disclosure will be described with reference to FIGS. 17A and 17B. FIGS. 17A and 17B are sectional views for describing an example of the configuration of the subpixel 100 according to the present embodiment and correspond to the drawing illustrated in the lower part of FIG. 4 described above. However, the present embodiment is different from the drawing illustrated in the lower part of FIG. 4 in that other layers are stacked on the rod-shaped lens 310 and the color filter 302. Specifically, FIGS. 17A and 17B are sectional views of the subpixel 100 taken along a direction perpendicular to the plane of the substrate 300.

In the present embodiment, layers that can be stacked on the rod-shaped lens 310 and the color filter 302 will be described.

In FIGS. 17A and 17B, for example, the color filter 302 may be stacked above the plurality of rod-shaped lenses 310, and the color filter 302 may be stacked below the plurality of rod-shaped lenses 310, as in the second embodiment of the present disclosure described with reference to FIGS. 7A and 7B. Furthermore, in the present embodiment, as illustrated in FIGS. 17A and 17B, a glass substrate 370 is stacked on the plurality of rod-shaped lenses 310 or the color filter 302 with a resin layer 360 interposed therebetween.

The resin layer 360 adheres to the glass substrate 370 to seal the light emitting device 10 and suppress entry of moisture into the inside. Specifically, in the present embodiment, a refractive index n3 of the resin layer 360 is preferably higher than the refractive index n2 of the peripheral portion 312 located around the rod-shaped lens 310. Furthermore, in the present embodiment, the refractive index n3 of the resin layer 360 is preferably close to the refractive index n1 of the rod-shaped lens 310. For example, the resin layer 360 is preferably formed by a material having the refractive index n3 of about 1.7 to 2. 0 at room temperature. Specifically, the resin layer 360 can be formed by, for example, a resin material such as an epoxy resin. In the present embodiment, by setting the refractive index n3 of the resin layer 360 in this manner, the light from the rod-shaped lens 310 and the parallel light can be efficiently extracted to the front upper side of the subpixel 100.

The glass substrate 370 can protect the subpixel 100 and the like. Specifically, the glass substrate 370 can be constituted by, for example, a glass substrate such as high strain point glass, soda glass, borosilicate glass, forsterite, lead glass, or quartz glass, a resin substrate such as polymethyl methacrylate, polyvinyl alcohol, polyvinyl phenol, polyether sulfone, polyimide, polycarbonate, polyethylene terephthalate, or polyethylene naphthalate, or the like.

### 8.2 Modification 1

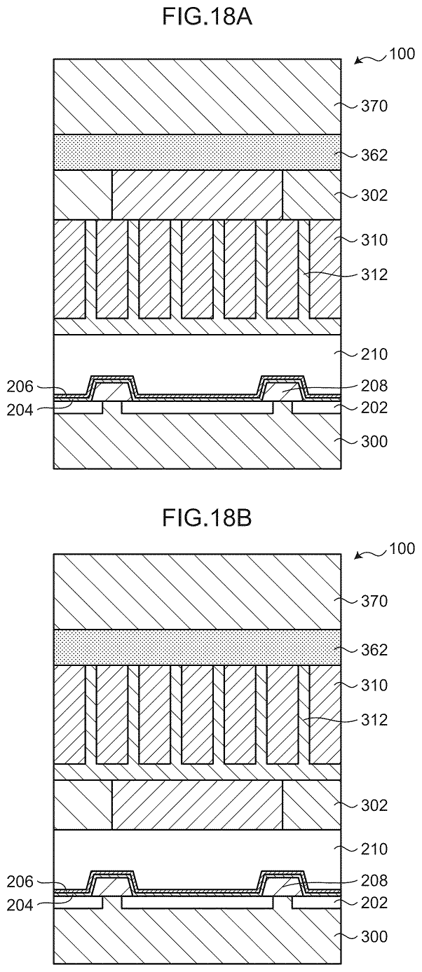

Next, Modification 1 of the sixth embodiment of the present disclosure will be described with reference to FIGS. 18A and 18B. FIGS. 18A and 18B are sectional views for describing an example of the configuration of the subpixel 100 according to Modification 1, and specifically, are sectional views when the subpixel 100 is cut in a direction perpendicular to the plane of the substrate 300.

Furthermore, in Modification 1, as illustrated in FIGS. 18A and 18B, unlike the present embodiment, a hollow layer (cavity) 362 is provided instead of the resin layer 360. The hollow layer 362 is a space in which a gas such as air (refractive index 1.0) is sealed.

Note that, in Modification 1, on an outer periphery of the light emitting device 10, an outer periphery of the glass substrate 370 is preferably sealed with a resin layer (not illustrated).

### 8.3 Modification 2

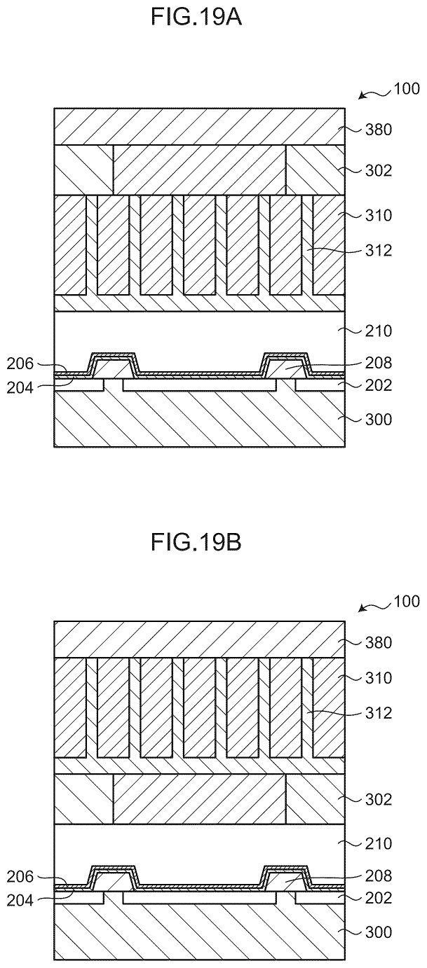

Next, Modification 2 of the sixth embodiment of the present disclosure will be described with reference to FIGS. 19A and 19B. FIGS. 19A and 19B are sectional views for describing an example of the configuration of the subpixel 100 according to Modification 2, and specifically, are sectional views when the subpixel 100 is cut in a direction perpendicular to the plane of the substrate 300.

Furthermore, in Modification 2, as illustrated in FIGS. 19A and 19B, unlike the present embodiment, a hard coat layer 380 is provided instead of stacking the resin layer 360 and the glass substrate 370. The hard coat layer 380 has a function of protecting the subpixel 100 and the like, and can suppress entry of moisture into the inside.

Specifically, in Modification 2, a refractive index n4 of the hard coat layer 380 is preferably higher than the refractive index n2 of the peripheral portion 312 located around the rod-shaped lens 310. Furthermore, in the present embodiment, the refractive index n4 of the hard coat layer 380 is preferably close to the refractive index n1 of the rod-shaped lens 310. For example, the hard coat layer 380 is preferably formed by a material having the refractive index n4 of about 1.7 to 2.0 at room temperature. In Modification 2, by setting the refractive index n4 of the hard coat layer 380 in this manner, the light from the rod-shaped lens 310 and the parallel light can be efficiently extracted to the front upper side of the subpixel 100.

Specifically, the hard coat layer 380 includes, for example, an ultraviolet curable resin. The ultraviolet curable resin may contain, for example, at least one selected from the group consisting of radically polymerized ultraviolet curable resins and cationically polymerized ultraviolet curable resins. The ultraviolet curable resin may include an additive as necessary. The additive may contain, for example, at least one selected from the group consisting of a sensitizer, a filler, a stabilizer, a leveling agent, an ultraviolet absorber, an antistatic agent, an antifoaming agent, a viscosity modifier, and the like. The ultraviolet curable resin may specifically include, for example, an acrylic ultraviolet curable resin.

In Modification 2, in order to improve characteristics such as scratch resistance and weather resistance of the light emitting device 10, pencil hardness of a surface of the hard coat layer 380 is preferably 4 H or more, more preferably 5 H or more, and more preferably 6 H or more from the viewpoint of improving characteristics such as the scratch resistance and the weather resistance of the light emitting device 10. Note that the pencil hardness of the surface of the hard coat layer 380 is measured in conformity with JIS K5600-5-4. The measurement is performed in an atmosphere at a temperature of 23±1° C. and a relative humidity of 50±5%,

Since the glass substrate 370 is not provided in Modification 2, unlike the present embodiment and Modification 1, the light emitting device 10 can be reduced in layer thickness and weight. In particular, when used in a mobile terminal, a head mounted display, or the like, the light emitting device 10 can be reduced in layer thickness and weight. Furthermore, in Modification 2, since the hard coat layer 380 can be manufactured in an existing semiconductor manufacturing step, the manufacturing cost and manufacturing time of the light emitting device 10 can be reduced.

Furthermore, in Modification 2, the upper surface of the hard coat layer 308 may be covered with an antireflection film. The antireflection film can suppress reflection of light by utilizing interference of light, and can improve the visibility of the light emitting device 10. The antireflection film may have, for example, a stacked structure in which a high refractive index film containing titanium oxide (TiOx), tantalum oxide (TaOx), niobium oxide (NbOx), or the like and a low refractive index film containing silicon oxide (SiOx), silicon oxynitride (SiON), or the like are alternately stacked.

In addition, in Modification 2, the hard coat layer 380 may be an inorganic multilayer film. In Modification 2, the inorganic multilayer film may have, for example, a function of protecting the subpixel 100 and the like and a function of suppressing reflection.

Specifically, the inorganic multilayer film may include, for example, a first thin film and a second thin film. The function of the inorganic multilayer film as an antireflection film can be obtained, for example, by controlling a refractive index and a thickness of the first thin film and the second thin film. Specifically, in this modification, one of the first thin film or the second thin film may be a low refractive index film, and the other one may be a high refractive index film. Furthermore, the inorganic multilayer film may be, for example, a stacked layer of three or more layers including these thin films.

For example, the first thin film is an atomic layer deposited film. Since the atomic layer deposited film is a dense film, the first thin film is an atomic layer deposited film, and the effect of suppressing moisture infiltration can be improved. The atomic layer deposited film can be formed by an atomic layer deposition method (ALD). The atomic layer deposited film contains, for example, a metal. oxide or a metal nitride. The metal oxide contains, for example, aluminum oxide (AlOx) or titanium oxide (TiOx). The metal nitride contains, for example, silicon nitride (SiNx) or titanium nitride (TiNx).

For example, the second thin film may be configured by a material different from the material of the first thin film. The second thin film is preferably a low temperature oxidation (LTO) film. When the second thin film is a low temperature oxide film, damage to the light emitting layer 204 at the time of formation of the second thin film can be suppressed. The low temperature oxide film is, for example, an atomic layer deposited film or a chemical vapor deposition film, and preferably an atomic layer deposited film. Since the atomic layer deposited film is a dense film, when the low temperature oxide film is an atomic layer deposited film, the effect of suppressing moisture infiltration into the inorganic multilayer film can be further improved.

The atomic layer deposited film can be formed by the atomic layer deposition method (ALD). The chemical vapor deposition film can be formed by the chemical vapor deposition (CVD) method. Examples of the CVD include thermal CVD, catalytic chemical vapor deposition, photo CVD, vacuum plasma CVD, and atmospheric pressure plasma CVD. The second thin film contains, for example, silicon oxide (SiOx), carbon-containing silicon oxide (SiOC), or the like.

Note that the present embodiment and modification are not limited to the configurations illustrated in FIGS. 17A to 19B, and can be appropriately changed in accordance with desired characteristics and the like.

### 9. Summary

As described above, in each embodiment of the present disclosure, by providing the plurality of rod-shaped lenses 310 on one subpixel 100, the light of the light emitting layer 204 can be efficiently extracted as parallel light to the front upper side of the subpixel 100. As a result, in the present embodiment, light can be efficiently incident on the set optical system, and the light emitting device 10 can be brighter and the visibility can be improved. Furthermore, in the present embodiment, since the light from the subpixel 100 can be efficiently incident on the set optical system, power consumption of the light emitting device 10 can be further reduced.

Note that, a case has been described where the embodiment of the present disclosure described above is applied to the light emitting device 10 having the set optical system. However, the present embodiment is not required to be applied to such a device, and can be applied to any light emitting device desired to efficiently extract parallel light to the front upper side of the device.

### 10. Modifications

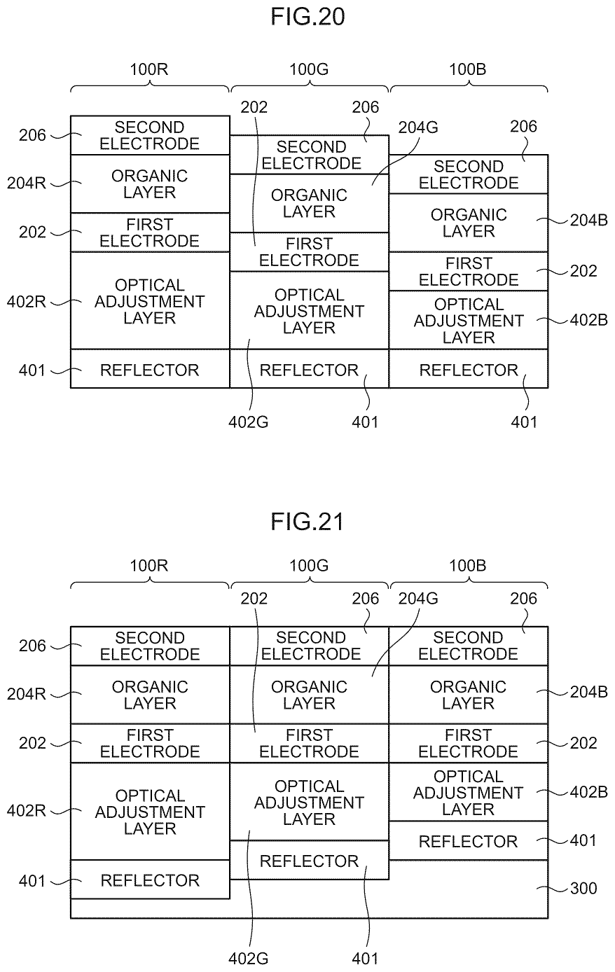

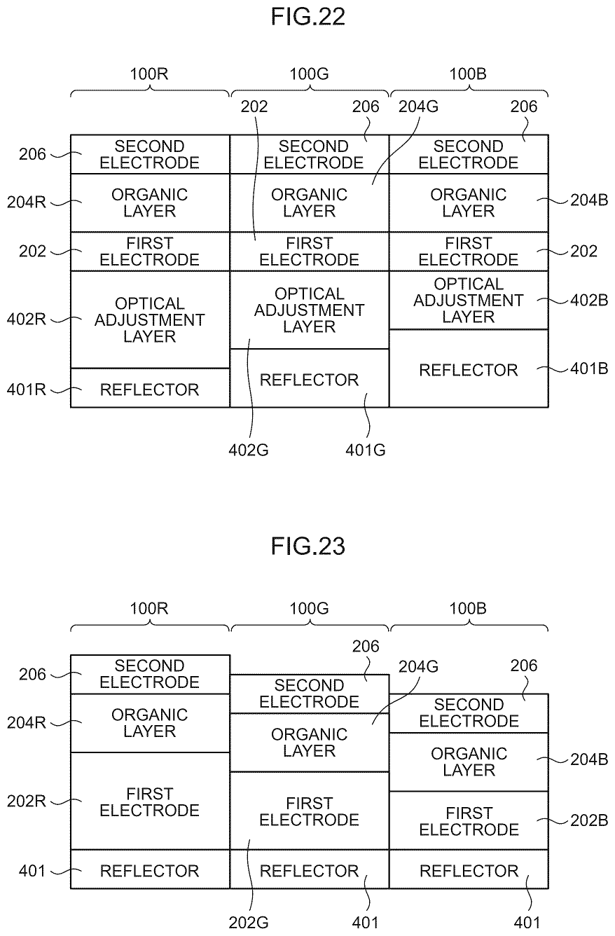

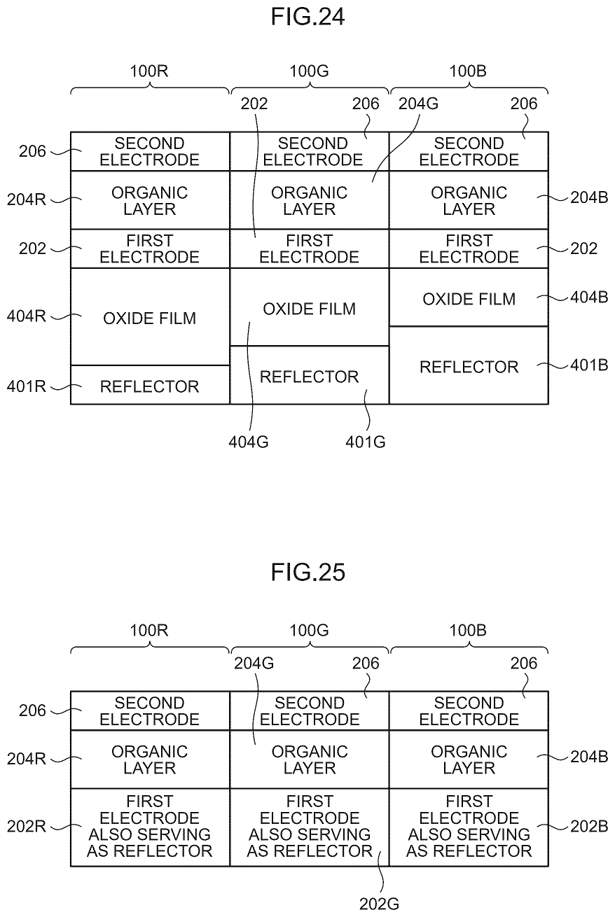

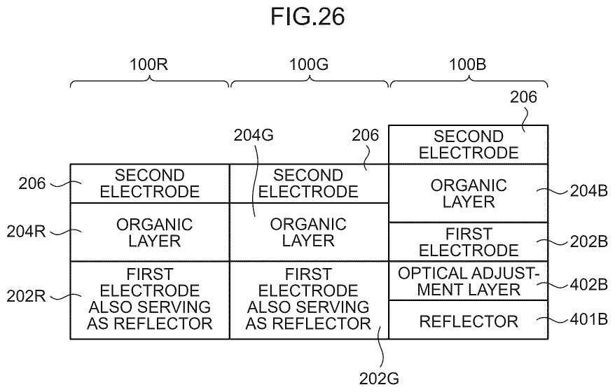

The subpixel 100 used in the light emitting device 10 according to the embodiment of the present disclosure described above may have a resonator structure that causes light generated in the light emitting layer 204 to resonate. Hereinafter, the resonator structure will be described with reference to FIGS. 20 to 26. FIG. 20 is a schematic sectional view for describing a first example of the resonator structure, FIG. 21 is a schematic sectional view for describing a second example of the resonator structure, and FIG. 22 is a schematic sectional view for describing a third example of the resonator structure. FIG. 23 is a schematic sectional view for describing a fourth example of the resonator structure, and FIG. 24 is a schematic sectional view for describing a fifth example of the resonator structure. Furthermore, FIG. 25 is a schematic sectional view for describing a sixth example of the resonator structure, and FIG. 26 is a schematic sectional view for describing a seventh example of the resonator structure.

### Resonator Structure: First Example

FIG. 20 is a schematic sectional view for describing the first example of the resonator structure. In the first example, the first electrode (for example, anode electrode) 202 is formed with a common film thickness in each subpixel 100. The same applies to the second electrode (for example, cathode electrode) 206.

As illustrated in FIG. 20, a reflector 401 is disposed below the first electrode 202 of the subpixel 100 with an optical adjustment layer 402 interposed therebetween. A resonator structure that causes light generated by an organic layer (specifically, the light emitting layer) 204 to resonate is formed between the reflector 401 and the second electrode 206.

The reflector 401 is formed with a common film thickness in each subpixel 100. The film thickness of the optical adjustment layer 402 varies depending on the color to be displayed by the subpixel 100. Since optical adjustment layers 402R, 402G, and 402B have different film thicknesses, it is possible to set an optical distance at which optimum resonance occurs for a wavelength of light corresponding to the color to be displayed.

In the example illustrated in FIG. 20, upper surfaces of the reflectors 401 in the subpixels 100R, 100G, and 100B are arranged so as to be aligned. As described above, since the film thickness of the optical adjustment layer 402 varies depending on the color to be displayed by the subpixel 100, the position of an upper surface of the second electrode 206 varies depending on the types of the subpixels 100R, 100G, and 100B.

The reflector 401 can be formed by using, for example, a metal such as aluminum (Al), silver (Ag), or copper (Cu), or an alloy containing these metals as a main component.

The optical adjustment layer 402 can be configured by using an inorganic insulating material such as silicon nitride (SiNx), silicon oxide (SiOx), or silicon oxynitride (SiOxNy), or an organic resin material such as an acrylic resin or a polyimide resin. The optical adjustment layer 402 may be a single layer or a stacked film of a plurality of materials. The number of stacked layers may be different according to the type of the subpixel 100.

The first electrode 202 can be formed by using, for example, a transparent conductive material such as indium tin oxide (ITO), indium: zinc oxide (IZO), or zinc oxide (ZnO).

The second electrode 206 preferably functions as a semi-transparent reflection film. The second electrode 206 can be formed by using magnesium (Mg), silver (Ag), a magnesium-silver alloy (MgAg) containing magnesium and silver as a main component, an alloy containing an alkali metal or an alkaline earth metal, or the like.

### Resonator Structure: Second Example

FIG. 21 is a schematic sectional view for describing the second example of the resonator structure. In the second example, too, the first electrode 202 and the second electrode 206 are formed with a common film thickness in each subpixel 100.

Then, in the second example, too, the reflector 401 is disposed below the first electrode 202 of the subpixel 100 with the optical adjustment layer 402 interposed therebetween. A resonator structure that causes light generated by the organic layer 204 to resonate is formed between the reflector 401 and the second electrode 206. As in the first example, the reflector 401 is formed with a common film thickness in each subpixel 100, and the film thickness of the optical adjustment layer 402 varies depending on the color to be displayed by the subpixel 100.

In the first example illustrated in FIG. 20, the upper surfaces of the reflectors 401 in the subpixels 100R, 100G, and 100B are arranged so as to be aligned, and the positions of the upper surfaces of the second electrodes 206 are different according to the types of the subpixels 100R, 100G, and 100B.

On the other hand, in the second example illustrated in FIG. 21, the upper surfaces of the second electrodes 206 are arranged so as to be aligned in the subpixels 100R, 100G, and 100B. In order to align the upper surfaces of the second electrodes 206, the upper surfaces of the reflectors 401 in the subpixels 100R, 100G, and 100B are disposed to be different according to the types of the subpixels 100R, 100G, and 100B. Therefore, lower surfaces of the reflectors 401 have a stepped shape according to the types of the subpixels 100R, 100G, and 100B.

Materials and the like constituting the reflector 401, the optical adjustment layer 402, the first electrode 202, and the second electrode 206 are similar to the contents described in the first example, and thus will not be described.

### Resonator Structure: Third Example

FIG. 22 is a schematic sectional view for describing the third example of the resonator structure. In the third example, too, the first electrode 202 and the second electrode 206 are formed with a common film thickness in each subpixel 100.

Then, in the third example, too, the reflector 401 is disposed below the first electrode 202 of the subpixel 100 with the optical adjustment layer 402 interposed therebetween. A resonator structure that causes light generated by the organic layer 204 to resonate is formed between the reflector 401 and the second electrode 206. As in the first example and the second example, the film thickness of the optical adjustment layer 402 varies depending on the color to be displayed by the subpixel 100. Then, as in the second example, the positions of the upper surfaces of the second electrodes 206 are arranged so as to be aligned in the subpixels 100R, 100G, and 100B.

In the second example illustrated in FIG. 21, in order to align the upper surfaces of the second electrodes 206, the lower surfaces of the reflectors 401 have a stepped shape according to the types of the subpixels 100R, 100G, and 100B.

On the other hand, in the third example illustrated in FIG. 22, the film thickness of the reflector 401 is set to be different according to the types of the subpixels 100R, 100G, and 100B. Specifically, the film thickness is set such that the lower surfaces of reflectors 401R, 401G, and 401B are aligned.

The materials and the like constituting the reflector 401, the optical adjustment layer 402, the first electrode 202, and the second electrode 206 are similar to the contents described in the first example, and thus will not be described.

### Resonator Structure: Fourth Example

FIG. 23 is a schematic sectional view for describing the fourth example of the resonator structure.

In the first example illustrated in FIG. 20, the first electrode 202 and the second electrode 206 of the subpixel 100 are formed with a common film thickness. Then, the reflector 401 is disposed below the first electrode 202 of the subpixel 100 with the optical adjustment layer 402 interposed therebetween.

On the other hand, in the fourth example illustrated in FIG. 23, the optical adjustment layer 402 is omitted, and the film thickness of the first electrode 202 is set to be different according to the types of the subpixels 100R, 100G, and 100B.

The reflector 401 is formed with a common film thickness in each subpixel 100. The film thickness of the first electrode 202 varies depending on the color to be displayed by the subpixel 100. Since first electrodes 202R, 202G, and 202B have different film thicknesses, it is possible to set an optical distance at which optimum resonance occurs for a wavelength of light corresponding to the color to be displayed.

The materials and the like constituting the reflector 401, the first electrode 202, and the second electrode 206 are similar to the contents described in the first example, and thus will not be described.

### Resonator Structure: Fifth Example

FIG. 24 is a schematic sectional view for describing the fifth example of the resonator structure,

In the first example illustrated in FIG. 20, too, the first electrode 202 and the second electrode 206 are formed with a common film thickness in each subpixel 100. Then, the reflector 401 is disposed below the first electrode 202 of the subpixel 100 with the optical adjustment layer 402 interposed therebetween.

On the other hand, in the fifth example illustrated in FIG. 24, the optical adjustment layer 402 is omitted, and instead, an oxide film 404 is formed on the surface of the reflector 401. The film thickness of the oxide film 404 is set to be different according to the types of the subpixels 100R, 100G, and 100B.

The film thickness of the oxide film 404 varies depending on the color to be displayed by the subpixel 100. Since oxide films 404R, 404G, and 404B have different film thicknesses, it is possible to set an optical distance at which optimum resonance occurs for a wavelength of light corresponding to the color to be displayed.

The oxide film 404 is a film obtained by oxidizing the surface of the reflector 401, and includes, for example, aluminum oxide, tantalum oxide, titanium oxide, magnesium oxide, zirconium oxide, or the like. The oxide film 404 functions as an insulating film for adjusting an optical path length (optical distance) between the reflector 401 and the second electrode 206.

The oxide film 404 having different film thicknesses depending on the types of the subpixels 100R, 100G, and 100B can be formed, for example, as follows.

First, an electrolytic solution is filled in a container, and a substrate on which the reflector 401 is formed is immersed in the electrolytic solution. An electrode is disposed so as to face the reflector 401.

Then, a positive voltage is applied to the reflector 401 with reference to the electrode, and the reflector 401 is anodized. The film thickness of the oxide film due to the anodic oxidation is proportional to a voltage value with respect to the electrode. Therefore, anodization is performed in a state where voltages corresponding to the types of the subpixels 100R, 100G, and 100B are applied to the reflectors 401R, 401G, and 401B, respectively. As a result, the oxide films 404 having different film thicknesses can be collectively formed.

The materials and the like constituting the reflector 401, the first electrode 202, and the second electrode 206 are similar to the contents described in the first example, and thus will not be described.

### Resonator Structure: Sixth Example

FIG. 25 is a schematic sectional view for describing the sixth example of the resonator structure. In the sixth example, the subpixel 100 is configured by stacking the first electrode 202, the organic layer 204, and the second electrode 206. However, in the sixth example, the first electrode 202 is formed to function as both an electrode and a reflector. The first electrode (also serving as a reflector) 202 is formed by a material having an optical constant selected in accordance with the type of the subpixels 100R, 100G, and 100B. Since a phase shift by the first electrode (also serving as a reflector) 202 is different, it is possible to set an optical distance at which optimum resonance occurs for a wavelength of light corresponding to the color to be displayed.

The first electrode (also serving as a reflector) 202 can be configured by a single metal such as aluminum (Al), silver (Ag), gold (Au), or copper (Cu), or an alloy containing these metals as a main component. For example, the first electrode (also serving as a reflector) 202R of the subpixel 100R can be formed by copper (Cu), and the first electrode (also serving as a reflector) 202G of the subpixel 100G and the first electrode (also serving as a reflector) 202B of the subpixel 100B may be formed by aluminum.

The material and the like constituting the second electrode 206 is similar to the content described in the first example, and thus will not be described.

### Resonator Structure: Seventh Example

FIG. 26 is a schematic sectional view for describing the seventh example of the resonator structure. In the seventh example, basically, the sixth example is applied to the subpixels 100R and 100G, and the first example is applied to the subpixel 100B. In this configuration, it is possible to set an optical distance at which optimum resonance occurs for a wavelength of light corresponding to the color to be displayed.

The first electrodes (also serving as reflectors) 202R and 202G used for the subpixels 100R and 100G can be configured by a single metal such as aluminum (Al), silver (Ag), gold (Au), or copper (Cu), or an alloy containing these metals as a main component.

The materials and the like constituting the reflector 401B, the optical adjustment layer 402B, and the first electrode 202B used in the subpixel 100B are similar to the contents described in the first example, and thus will not be described.

### 11. Application Examples

For example, the technology of the present disclosure may be applied to a display unit or the like of various electronic apparatuses. Hereinafter, an example of an electronic apparatus to which the present technology can be applied will be described.

### Specific Example 1

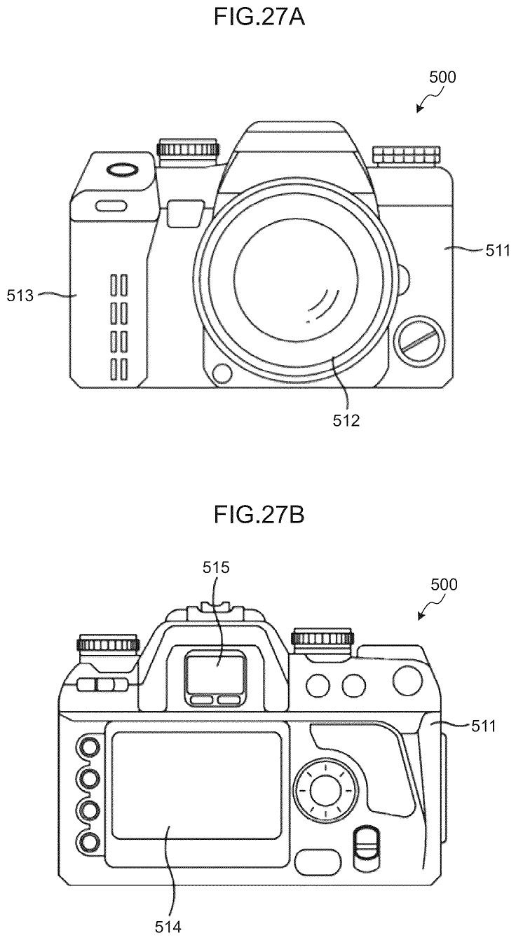

FIG. 27A is a front view illustrating an example of an external appearance of a digital still camera 500, and FIG. 27B is a rear view illustrating an example of the external appearance of the digital still camera 500. The digital still camera 500 is of a lens interchangeable single lens reflex type, and includes an interchangeable imaging lens unit (interchangeable lens) 512 substantially at a center of a front of a camera body 511, and a grip 513 to be held by a photographer on a front left side.

A monitor 514 is provided at a position shifted to the left side from a center of a back surface of the camera body 511. An electronic view finder (eyepiece window) 515 is provided above the monitor 514. By looking into the electronic view finder 515, the photographer can determine the composition by visually recognizing an optical image of a subject guided from the imaging lens unit 512. As the monitor 514 and the electronic view finder 515, the light emitting device 10 according to the embodiment of the present disclosure can be used.

### Specific Example 2

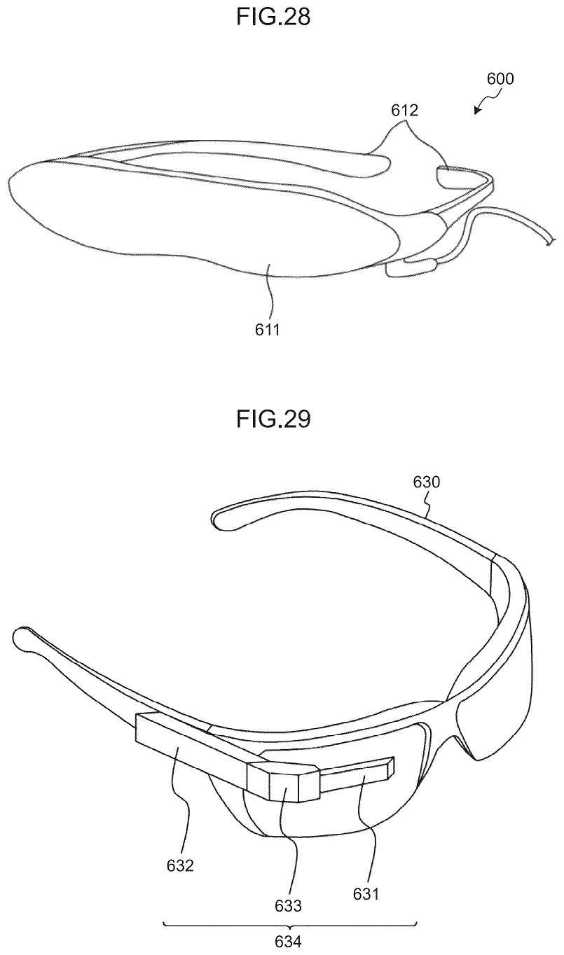

FIG. 28 is an external view of a head mounted display 600. The head mounted display 600 includes, for example, ear hooks 612 to be worn on the head of a user on both sides of an eyeglass-shaped display unit 611. In the head mounted display 600, the light emitting device 10 according to the embodiment of the present disclosure can be used as the display unit 611.

### Specific Example 3

FIG. 29 is an external view of a see-through head mounted display 634. The see-through head mounted display 634 includes a body 632, an arm 633, and a lens barrel 631.

The body 632 is connected to the arm 633 and an eyeglass 630. Specifically, an end of the body 632 in a long side direction is coupled to the arm 633, and one side of a side surface of the body 632 is coupled to the eyeglass 630 via a connecting member. Note that the body 632 may be directly mounted on the head of a human body.

The body 632 incorporates a control board for controlling an operation of the see-through head mounted display 634 and a display unit. The arm 633 connects the body 632 and the lens barrel 631 and supports the lens barrel 631. Specifically, the arm 633 is coupled to the end of the body 632 and an end of the lens barrel 631, and fixes the lens barrel 631. The arm 633 incorporates a signal line for communicating data related to an image provided from the body 632 to the lens barrel 631.

The lens barrel 631 projects image light provided from the body 632 via the arm 633 toward the eyes of the user wearing the see-through head mounted display 634 through an eyepiece. In the see-through head mounted display 634, the light emitting device 10 according to the embodiment of the present disclosure can be used for the display unit of the body 632.

### Specific Example 4

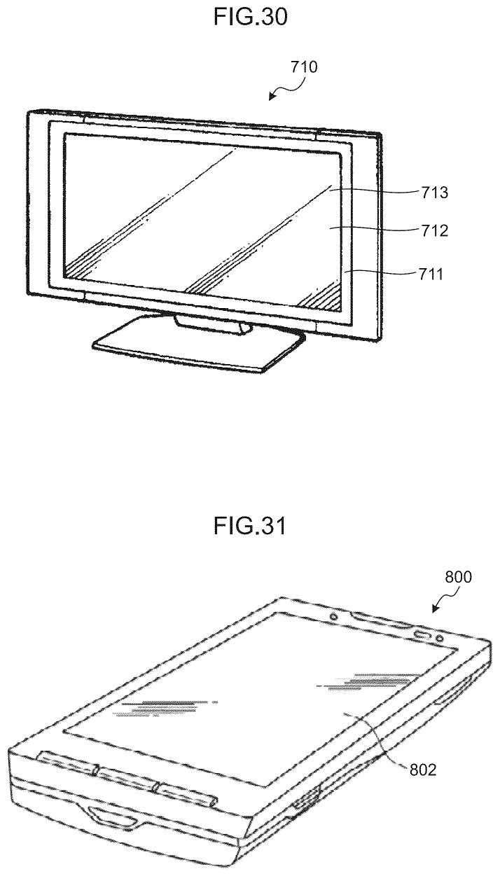

FIG. 30 illustrates an example of an external appearance of a television apparatus 710. The television apparatus 710 includes, for example, a video display screen unit 711 including a front panel 712 and a filter glass 713, and the video display screen unit 711 includes the light emitting device 10 according to the embodiment of the present disclosure.

### Specific Example 5

FIG. 31 illustrates an example of an external appearance of a smartphone 800. The smartphone 800 includes a display unit 802 that displays various types of information, an operation unit including a button that receives an operation input by the user, and the like. The display unit 802 can be the light emitting device 10 according to the present embodiment.

### Specific Example 6

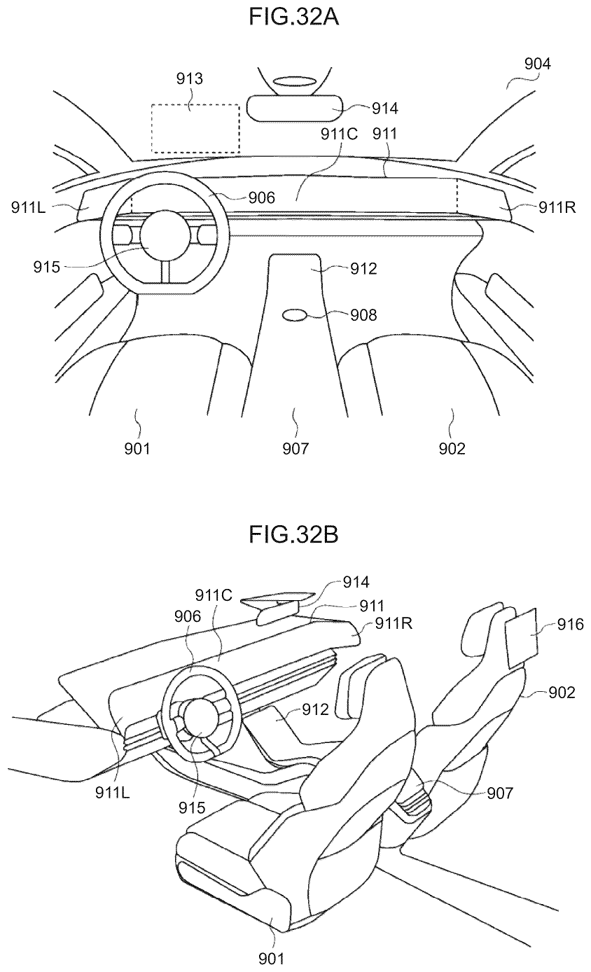

FIGS. 32A and 32B are diagrams illustrating an internal configuration of an automobile having the light emitting device 10 according to the embodiment of the present disclosure as a display device, Specifically, FIG. 32A is a diagram illustrating a state of the inside of the automobile from the rear to the front of the automobile, and FIG. 32B is a diagram illustrating a state of the inside of the automobile from the oblique rear to the oblique front of the automobile.

The automobile illustrated in FIGS. 32A and 32B has a center display 911, a console display 912, a head-up display 913, a digital rear mirror 914, a steering wheel display 915, and a rear entertainment display 916. The light emitting device 10 according to the embodiment of the present disclosure can be applied to some or all of the above displays.

The center display 911 is disposed on a center console 907 at a position facing a driver's seat 901 and a passenger seat 902. FIGS. 32A and 32B illustrate an example of the center display 911 having a horizontally long shape extending from the driver's seat 901 toward the passenger seat 902, but the screen size and the arrangement place of the center display 911 are arbitrary. The center display 911 can display information detected by various sensors (not illustrated). As a specific example, the center display 911 can display a captured image captured by an image sensor, a distance image indicating a distance to an obstacle in front of or on a side of the automobile measured by a time of flight (ToF) sensor, a body temperature of a passenger detected by an infrared sensor, and the like. The center display 911 can be used to display, for example, at least one of safety related information, operation related information, a life log, health related information, authentication and identification related information, or entertainment related information.

The safety related information is information such as doze detection, distraction detection, detection of a prank by a child riding together, presence or absence of attachment of a seat belt, and detection of a left occupant, and is information detected by, for example, a sensor (not illustrated) superimposed on a back side of the center display 1911. The operation related information detects a gesture related to an operation of the occupant by using a sensor. The detected gesture may include operation of various equipment in the automobile. For example, the sensor detects operations of air conditioning equipment, a navigation device, an audio/visual (AV) device, a lighting device, and the like. The life log includes a life log of all the occupants. For example, the life log includes an action record of each occupant in the automobile. By acquiring and saving the life log, it is possible to confirm the state of the occupant at the time of an accident. The health related information detects the temperature of the occupant by using a temperature sensor, and estimates the health state of the occupant on the basis of the detected temperature. Alternatively, the face of the occupant may be imaged by using an image sensor, and the health state of the occupant may be estimated from an imaged facial expression. Furthermore, a conversation may be made with the occupant in an automatic voice, and the health condition of the occupant may be estimated on the basis of a response content of the occupant. The authentication and identification related information includes a keyless entry function of performing face authentication by using a sensor, an automatic adjustment function of a seat height and a position by using face identification, and the like. The entertainment related information includes a function of detecting operation information of an AV device by the occupant by using a sensor, a function of recognizing the face of the occupant by the sensor and providing content suitable for the occupant by the AV device, and the like.

The console display 912 can be used to display life log information, for example. The console display 912 is disposed near a shift lever 908 of the center console 907 between the driver's seat 901 and the passenger seat 902. The console display 912 can also display information detected by various sensors (not illustrated). The console display 912 may display an image of a periphery of a vehicle captured by an image sensor, or may display a distance image indicating a distance to an obstacle in the periphery of the vehicle.

The head-up display 913 is virtually displayed behind a windshield 904 in front of the driver's seat 901. The head-up display 913 can be used to display, for example, at least one of the safety related information, the operation related information, the life log, the health related information, the authentication and identification related information, or the entertainment related information. Since the head-up display 913 is virtually disposed in front of the driver's seat 901 in many cases, the head-up display is suitable for displaying information directly related to an operation of the automobile such as a speed of the automobile and a remaining amount of fuel (battery).

The digital rear mirror 914 can display not only the rear of the automobile but also the state of the occupant in the back seat, and thus can be used to display the life log information, for example, by arranging a sensor (not illustrated) to overlap a back surface side of the digital rear mirror 914.

The steering wheel display 915 is disposed near the center of a steering wheel 906 of the automobile. The steering wheel display 915 can be used to display, for example, at least one of the safety related information, the operation related information, the life log, the health related information, the authentication and identification related information, or the entertainment related information. In particular, the steering wheel display 915, which is near a hand of the driver, is suitable for displaying the life log information such as the temperature of the driver, or for displaying information related to the operation of the AV device, the air conditioning equipment, and the like.

The rear entertainment display 916 is attached to a back side of the driver's seat 901 and the passenger seat 902, and is for viewing by the occupant in the back seat. The rear entertainment display 916 can be used to display, for example, at least one of the safety related information, the operation related information, the life log, the health related information, the authentication and identification related information, or the entertainment related information. In particular, the rear entertainment display 916, which is in front of the occupant in the back seat, displays information related to the occupant in the back seat. For example, information related to the operation of the AV device or the air conditioning equipment may be displayed, or a result of measuring the temperature or the like of the occupant in the back seat by a temperature sensor (not illustrated) may be displayed.

### 12. Supplement

Although the preferred embodiments of the present disclosure have been described in detail with reference to the accompanying drawings, the technical scope of the present disclosure is not limited to such examples. It is obvious that a person having ordinary knowledge in the technical field of the present disclosure can conceive a combination of various embodiments and various changes or modifications within the scope of the technical idea described in the claims, and it is naturally understood that the combination and the changes or modifications also belong to the technical scope of the present disclosure.

Furthermore, the effects described in the present specification are merely illustrative or exemplary, and are not restrictive. That is, the technology of the present disclosure can exhibit other effects obvious to those skilled in the art from the description of the present specification together with or instead of the above effects.

Note that the present technology can also have the following configurations.
(1) A light emitting device comprising a plurality of light emitting elements arranged on a substrate, wherein
   each of the plurality of light emitting elements includes
   a first electrode provided on the substrate,
   a light emitting layer that is stacked on the first electrode and emits light,
   a second electrode that is stacked on the light emitting layer and transmits the light from the light emitting layer, and
   a plurality of rod-shaped lenses provided above the second electrode, and
   the plurality of rod-shaped lenses is provided apart from each other.
(2) The light emitting device according to (1), wherein
   a peripheral region provided around the plurality of rod-shaped lenses has a refractive index lower than a refractive index of the plurality of rod-shaped lenses.
(3) The light emitting device according to (2), wherein three or more of the rod-shaped lenses are provided for one of the light emitting elements.
(4) The light emitting device according to (2) or (3), wherein a diameter of the plurality of rod-shaped lenses has a length equal to or longer than a wavelength of light emitted from the light emitting element.
(5) The light emitting device according to any one of (2) to (4), wherein
   the refractive index of the plurality of rod-shaped lenses is from 1.6 to 2.1.
(6) The light emitting device according to (5), wherein
   the refractive index of the peripheral region is from 1.0 to 1.7.
(7) The light emitting device according to any one of (2) to (6), wherein the plurality of rod-shaped lenses has a tapered shape expanding downward in a stacking direction of the light emitting elements.
(8) The light emitting device according to any one of (2) to (7), wherein a lower end of the plurality of rod-shaped lenses has a condenser lens shape.
(9) The light emitting device according to any one of (2) to (7), wherein an upper end of the plurality of rod-shaped lenses has a condenser lens shape.
(10) The light emitting device according to any one of (2) to (9), wherein the plurality of rod-shaped lenses has a polygonal shape, a circular shape, or an elliptical shape in plan view.
(11) The light emitting device according to any one of (2) to (10), wherein the plurality of rod-shaped lenses has different diameters in plan view.
(12) The light emitting device according to any one of (2) to (11), wherein the plurality of rod-shaped lenses includes at least one material selected from the group consisting of silicon nitride, silicon oxynitride, titanium oxide, and an epoxy resin.
(13) The light emitting device according to any one of (2) to (11), wherein the peripheral region includes at least one material selected from the group consisting of air, silicon oxide, aluminum oxide, an acrylic resin, and an epoxy resin.
(14) The light emitting device according to any one of (2) to (13), further comprising
   a protective film that is stacked on the second electrode and transmits the light from the light emitting layer, wherein
   the plurality of rod-shaped lenses is provided on the protective film.
(15) The light emitting device according to any one of (2) to (13), further comprising
   a protective film that is stacked on the second electrode and transmits the light from the light emitting layer, wherein
   the plurality of rod-shaped lenses is provided in the protective film.
(16) The light emitting device according to any one of (2) to (15), further comprising a color filter stacked above the plurality of rod-shaped lenses.
(17) The light emitting device according to (16), further comprising a glass substrate above the color filter.
(18) The light emitting device according to (16), further comprising a hard coat layer above the color filter.
(19) The light emitting device according to any one of (2) to (18), further comprising an on-chip lens stacked below the plurality of rod-shaped lenses.
(20) The light emitting device according to any one of (2) to (14), further comprising a color filter stacked below the plurality of rod-shaped lenses.
(21) The light emitting device according to (20), further comprising a glass substrate above the plurality of rod-shaped lenses.
(22) The light emitting device according to (20), further comprising a hard coat layer above the plurality of rod-shaped lenses.
(23) The light emitting device according to (17) or (21), further comprising a resin layer or a hollow layer below the glass substrate.
(24) The light emitting device according to (18) or (22), wherein the hard coat layer includes an antireflection layer including a stack of films having different refractive indexes.
(25) The light emitting device according to any one of (2) to (13), wherein
   the plurality of rod-shaped lenses includes a conductive material, and
   the rod-shaped lenses adjacent to each other are connected to each other above the rod-shaped lenses.
(26) An electronic apparatus equipped with a light emitting device including a plurality of light emitting elements arranged on a substrate, wherein
   each of the plurality of light emitting elements includes
   a first electrode provided on the substrate,
   a light emitting layer that is stacked on the first electrode and emits light,
   a second electrode that is stacked on the light emitting layer and transmits the light from the light emitting layer, and
   a plurality of rod-shaped lenses provided above the second electrode, and
   the plurality of rod-shaped lenses is provided apart from each other.

### REFERENCE SIGNS LIST

10 LIGHT EMITTING DEVICE
11 HORIZONTAL DRIVE CIRCUIT
12 VERTICAL DRIVE CIRCUIT
20 PIXEL
100, 100a, 100B, 100G, 100R SUBPIXEL
202, 202B, 202G, 202R ANODE ELECTRODE
204, 204B, 204G, 204R LIGHT EMITTING LAYER
206 CATHODE ELECTRODE
208 INSULATING FILM
210 PROTECTIVE FILM
300 SUBSTRATE
302 COLOR FILTER
304 ON-CHIP LENS
310 ROD-SHAPED LENS
310a LENS MATERIAL
312, 322 PERIPHERAL PORTION
320 CONTACT
350, 352 TRENCH
360 RESIN LAYER
362 HOLLOW LAYER
370 GLASS SUBSTRATE
380 HARD COAT LAYER
401, 401B, 401G, 401R REFLECTOR
402, 402B, 402G, 402F OPTICAL ADJUSTMENT LAYER
404 404B, 404G, 404R OXIDE FILM
500 DIGITAL STILL CAMERA
511 CAMERA BODY
512 IMAGING LENS UNIT
513 GRIP
514 MONITOR
515 ELECTRONIC VIEW FINDER
600 HEAD MOUNTED DISPLAY
611, 802 DISPLAY UNIT
612 EAR HOOK
630 EYEGLASS
631 LENS BARREL
632 BODY
633 ARM
634 SEE-THROUGH HEAD MOUNTED DISPLAY
710 TELEVISION APPARATUS
711 VIDEO DISPLAY SCREEN UNIT
712 FRONT PANEL
713 FILTER GLASS
800 SMARTPHONE
901 DRIVER'S SEAT
902 PASSENGER SEAT
904 WINDSHIELD
906 STEERING WHEEL
907 CENTER CONSOLE
908 SHIFT LEVER
911 CENTER DISPLAY
912 CONSOLE DISPLAY
913 HEAD-UP DISPLAY
914 DIGITAL REAR MIRROR
915 STEERING WHEEL DISPLAY
916 REAR ENTERTAINMENT DISPLAY
C1 CAPACITY PORTION
C_{EL} CAPACITANCE
DTLn SIGNAL LINE
ELP LIGHT EMITTING ELEMENT
PS1m FEED LINE
PS2 COMMON FEED LINE
SCLm SCANNING LINE
TRw WRITE TRANSISTOR
TR_{D} DRIVE TRANSISTOR

1. A light emitting device comprising a plurality of light emitting elements arranged on a substrate, wherein
each of the plurality of light emitting elements includes
a first electrode provided on the substrate,
a light emitting layer that is stacked on the first electrode and emits light,
a second electrode that is stacked on the light emitting layer and transmits the light from the light emitting layer, and
a plurality of rod-shaped lenses provided above the second electrode, and
the plurality of rod-shaped lenses is provided apart from each other.

2. The light emitting device according to claim 1, wherein
a peripheral region provided around the plurality of rod-shaped lenses has a refractive index lower than a refractive index of the plurality of rod-shaped lenses.

3. The light emitting device according to claim 2, wherein three or more of the rod-shaped lenses are provided for one of the light emitting elements.

4. The light emitting device according to claim 2, wherein a diameter of the plurality of rod-shaped lenses has a length equal to or longer than a wavelength of light emitted from the light emitting element.

5. The light emitting device according to claim 2, wherein
the refractive index of the plurality of rod-shaped lenses is from 1.6 to 2.1.

6. The light emitting device according to claim 5, wherein
the refractive index of the peripheral region is from 1.0 to 1.7.

7. The light emitting device according to claim 2, wherein the plurality of rod-shaped lenses has a tapered shape expanding downward in a stacking direction of the light emitting elements.

8. The light emitting device according to claim 2, wherein a lower end of the plurality of rod-shaped lenses has a condenser lens shape.

9. The light emitting device according to claim 2, wherein an upper end of the plurality of rod-shaped lenses has a condenser lens shape.

10. The light emitting device according to claim 2, wherein the plurality of rod-shaped lenses has a polygonal shape, a circular shape, or an elliptical shape in plan view.

11. The light emitting device according to claim 2, wherein the plurality of rod-shaped lenses has different diameters in plan view.

12. The light emitting device according to claim 2, wherein the plurality of rod-shaped lenses includes at least one material selected from the group consisting of silicon nitride, silicon oxynitride, titanium oxide, and an epoxy resin.

13. The light emitting device according to claim 2, wherein the peripheral region includes at least one material selected from the group consisting of air, silicon oxide, aluminum oxide, an acrylic resin, and an epoxy resin.

14. The light emitting device according to claim 2, further comprising
a protective film that is stacked on the second electrode and transmits the light from the light emitting layer, wherein
the plurality of rod-shaped lenses is provided on the protective film.

15. The light emitting device according to claim 2, further comprising
a protective film that is stacked on the second electrode and transmits the light from the light emitting layer, wherein
the plurality of rod-shaped lenses is provided in the protective film.

16. The light emitting device according to claim 2, further comprising a color filter stacked above the plurality of rod-shaped lenses.

17. The light emitting device according to claim 2, further comprising an on-chip lens stacked below the plurality of rod-shaped lenses.

18. The light emitting device according to claim 2, further comprising a color filter stacked below the plurality of rod-shaped lenses.

19. The light emitting device according to claim 2, wherein
the plurality of rod-shaped lenses includes a conductive material, and
the rod-shaped lenses adjacent to each other are connected to each other above the rod-shaped lenses.

20. An electronic apparatus equipped with a light emitting device including a plurality of light emitting elements arranged on a substrate, wherein
each of the plurality of light emitting elements includes
a first electrode provided on the substrate,
a light emitting layer that is stacked on the first electrode and emits light,
a second electrode that is stacked on the light emitting layer and transmits the light from the light emitting layer, and
a plurality of rod-shaped lenses provided above the second electrode, and
the plurality of rod-shaped lenses is provided apart from each other.
